(19) United States
(12) Patent Application Publication
(10) Pub. No.: US 2015/0207067 A1
(43) Pub. Date: Jul. 23, 2015

(54) METAL OXIDE STRUCTURES, DEVICES & FABRICATION METHODS

(71) Applicant: Georgia Tech Research Corporation, Atlanta, GA (US)

(72) Inventors: W. Alan Doolittle, Hampton, GA (US); Walter E. Henderson, Atlanta, GA (US)

(21) Appl. No.: 14/614,716

(22) Filed: Feb. 5, 2015

Related U.S. Application Data
(63) Continuation of application No. 13/380,589, filed on Jul. 9, 2012.
(60) Provisional application No. 61/355,495, filed on Jun. 16, 2010.
(60) Provisional application No. 61/220,366, filed on Jun. 25, 2009.

(51) Int. Cl. H01L 45/00; H01L 27/24

(52) U.S. Cl. CPC H01L 45/08; H01L 45/147; H01L 45/1233; H01L 45/1206; H01L 27/2463

(57) ABSTRACT

Metal oxide structures, devices, and fabrication methods are provided. In addition, applications of such structures, devices, and methods are provided. In some embodiments, an oxide material can include a substrate and a single-crystal epitaxial layer of an oxide composition disposed on a surface of the substrate, where the oxide composition is represented by ABO₂ such that A is a lithium cation, B is a cation selected from the group consisting of trivalent transition metal cations, trivalent lanthanide cations, trivalent actinide cations, trivalent p-block cations, and combinations thereof, and O is an oxygen anion. The unit cell of the crystal structure of the oxide composition can be characterized by first layer of a plane of lithium cations and a second layer of a plurality of edge-sharing octahedra having a B cation positioned in a center of each octahedron and an oxygen anion at each corner of each octahedron. The first layer and the second layer of the unit cell are alternatingly stacked along one axis of the unit cell. Other aspects, features, and embodiments are also claimed and described.

### CROSS REFERENCE TO RELATED APPLICATIONS

This is a continuation application claiming priority under 35 U.S.C. §121 to U.S. patent application Ser. No. 13/380,589, filed 9 Jul. 2012, which claims under 35 U.S.C. §119 the benefit of and priority to International Patent Application Serial Number PCT/US2010/0040108, filed 25 Jun. 2010, and U.S. Provisional Patent Application Ser. No. 61/220,366 (filed 25 Jun. 2009) and 61/355,495 (filed 16 Jun. 2010), all of which are incorporated by reference herein as if fully set forth below in their entireties.

### STATEMENT OF FEDERALLY SPONSORED RESEARCH

This invention was made with Government support under Grant Number N00014-04-0426, awarded by the U.S. Navy. The U.S. Government has certain rights in this invention.

### TECHNICAL FIELD

Various embodiments of the present invention relate generally to semiconductor materials. Some of the various embodiments of the present invention more particularly relate to lithium-containing metal oxide semiconductor compositions, methods of fabricating such compositions, and end-product applications and devices incorporating these compositions.

### BACKGROUND

Metal oxides are employed in a variety of applications owing to their ability to adopt unusual structures, which can result in beneficial chemical and/or physical characteristics. For example, layered oxide structures exhibit a wide variety of important technological uses because they offer a unique crystalline architecture that can be designed to achieve specific properties.

While ubiquitous, there are limitations with such materials. For example, there traditionally has been a difficulty fabricating oxide semiconductors that are p-type. In contrast, n-type oxide semiconductors are relatively easy to fabricate. Of the p-type oxide semiconductors that are known, many are impractical for use as a result of their low conductivities, low carrier concentrations, low carrier mobilities, and/or high manufacturing costs. Thus, there remains a need in the art for improved p-type oxide semiconductors. It would be advantageous if a single structure type or composition could be used as the parent/base structure or composition to produce improved p-type semiconductor oxides and practical n-type semiconductor oxides.

It is to the provision of such improved semiconductor oxides that some of the various embodiments of the present invention are directed. Advantageously, the base structure or composition used to fabricate improved p-type semiconductor oxides can also be used to fabricate practical n-type materials.

### BRIEF SUMMARY

Embodiments of the present invention are directed to various semiconductor devices, structures, compositions, and fabrication methods. Devices include memristors, memdioes, memory arrays incorporating memristor cells, memtransistors, solar cells, hydrogen generators as well as others discussed below. The novel compositions and structures discussed herein in this application possess advantages and properties that enable a number of applications. Certain embodiments are discussed in this summary section for introduction but the full scope of this application is that covered by the claims located below.

Broadly speaking, according to some embodiments of the present invention, an oxide material includes a substrate and a single-crystal epitaxial layer of an oxide composition disposed on a surface of the substrate. With respect to the substrate, it can be a single-crystal substrate. In some cases, the substrate comprises a hexagonal crystal lattice.

The oxide composition can be represented by ABO₂ such that A is a lithium cation, B is a cation selected from the group consisting of trivalent transition metal cations, trivalent lanthanide cations, trivalent actinide cations, trivalent p-block cations, and combinations thereof, and O is an oxygen anion. More specifically, B can be niobium, cobalt, iron, nickel, or some combination thereof.

A unit cell of a crystal structure of the oxide composition can include a first layer comprising a plane of lithium cations and a second layer comprising a plurality of edge-sharing octahedra having a B cation positioned in a center of each octahedron and an oxygen anion at each corner of each octahedron. The first layer and the second layer of the unit cell can be alternatingly stacked along one axis of the unit cell.

The crystal structure of the oxide composition can adopt many forms. In some cases, the crystal structure of the oxide composition has a same structure as α-NaFeO₂.

It is possible for up to one-half of sites for the lithium cations in the oxide composition to be vacant such that the oxide composition exhibits p-type conductivity. In such cases, the p-type conductivity can be greater than about 1000 Siemens per centimeter. In some cases, however, the p-type conductivity can be greater than about 2000 Siemens per centimeter.

Similarly, up to about ten percent of oxygen anion sites at the corners of the octahedra can be vacant such that the oxide composition exhibits n-type conductivity. In such cases, the n-type conductivity can be greater than about 1000 Siemens per centimeter. In some cases, however, the n-type conductivity can be greater than about 2000 Siemens per centimeter.

It should be noted that the oxide material can include two or more single-crystal epitaxial layers of an oxide composition that are disposed on the surface of the substrate. These oxide compositions can have the same or different B cations. For example, in some cases, the B cations of the two or more oxide compositions are different for each of the two or more single-crystal epitaxial layers. In some cases, the oxide compositions of the second or more (i.e., any layer not most adjacent to the substrate) single-crystal epitaxial layers do not have to adopt the same crystal structure or have the same unit cell as the first (i.e., the layer most adjacent to the substrate) single-crystal epitaxial layer.

A single oxide composition can be intrinsically doped to exhibit a conductivity exceeding about 1000 Siemens per centimeter in either n-type or p-type configurations. Similarly, a single oxide composition can exhibit a minority carrier lifetime exceeding about 1 microsecond.

According to some embodiments of the present invention, a method of fabricating an oxide material can include providing a substrate, and growing a single-crystal epitaxial layer of an oxide composition on a surface of the substrate. In general, the substrate and/or the oxide composition can have any of the features described above for the oxide material embodiments.

The method can also include growing an additional single-crystal epitaxial layer of an oxide composition on a surface of the grown oxide composition. The additional single-crystal epitaxial layer of the oxide composition can have a B cation that is different than the B cation of the oxide composition on which the additional single-crystal epitaxial layer is grown. In some cases, the growing technique is one of the many forms of molecular beam epitaxy. A precursor source of the B cation of the oxide composition can be a halide composition.

Embodiments of the present invention can also include semiconductor devices that generally include a first variable resistance material and a second variable resistance material. A first layer of the first variable resistance material can define a first surface. The first variable resistance material can be programmable to be one of an n-type or a p-type material. A second layer of the second variable resistance material can define a second surface. The second variable resistance material can be programmable to be one of an n-type or a p-type material. The first layer can be disposed proximate the second layer with the first surface and the second surface being positioned proximate each other. The proximate first and second surfaces can define a boundary interface between the first and second layers. An electrical charge source in electrical communication with the first and second layers can supply a charge. The charge can program resistances for the first variable resistance material and the second variable resistance material.

Semiconductor devices of the present invention can include additional features. For example, layer materials (such as first and second layers) can be formed with metal oxide semiconductor materials (as discussed herein). Layer materials can also be formed with, and in some embodiments, consist only of Lithium Niobite (LiNbO₂). Some semiconductor devices can include a first electrode in electrical communication with a first layer and a second electrode in electrical communication with the second layer. The first and second electrodes can be an electrical charge source by supplying an electric potential. Some semiconductor devices can include a third layer of a third variable resistance material that defines a third surface. The third variable resistance material can be programmable to be one of an n-type or a p-type material. The third layer can be positioned proximate a co-positioned second layer to form a second interface boundary and also being in electrical communication with the charge source.

Some semiconductor devices can also possess additional features. For example, a semiconductor's layer materials can be formed in polygonal or circular shapes. Layer materials forming a semiconductor can be part of a memory cell, a memristor, a memdiode, a memtransistor, or charge storage device. Layer materials can be doped at varying density levels. In some embodiments the electrical charge source can be a radial electrode disposed to apply an electric charge between an inner electrode and an outer electrode, the radial electrode being positioned on the first layer. Layer materials of the present invention can also comprise ions/dopants that flux in response to the charge from the electric charge source.

Another semiconductor embodiment of the present invention generally includes a first electrode, a second electrode, and a metal-oxide-semiconductor region. The metal-oxide-semiconductor region can be disposed in electrical communication with the first electrode and the second electrode The metal-oxide-semiconductor region can comprise a first epitaxial metal layer doped at a first doped level, a second epitaxial metal layer doped at a second doped level, and a third epitaxial metal layer doped at a third doped level. The first epitaxial layer, the second epitaxial layer, and the third epitaxial layer can be positioned proximate to each other to form a first boundary interface between the first epitaxial layer and the second epitaxial layer and a second boundary interface between the second epitaxial layer and the third epitaxial layer. The first epitaxial layer, the second epitaxial layer, and the third epitaxial layer can comprise a material enabling ion movement across the first and second boundary interfaces to enable varying resistance of the metal-oxide-semiconductor region. The first and second electrodes can be configured to apply an electric potential across the metal-oxide-semiconductor region to enable ion/dopant flux across the first and second boundary interfaces. The metal-oxide semiconductor region can be part of a memory cell, memristor, memdiode, memtransistor, or a charge storage device. A semiconductor device can also comprise a dielectric or a ferroelectric material situated on a portion of the metal-oxide-semiconductor region and intermediate the first and second electrodes, and further comprise a third electrode situated in electrical contact or communication with the dielectric or the ferroelectric material.

Semiconductor embodiments incorporating epitaxial layers can include various features. For example, the first and the third epitaxial metal layers can be formed of a first material and the second epitaxial metal layer being formed of a different material so that the metal-oxide semiconductor region is a symmetric heterostructure. The first epitaxial layer, the second epitaxial layer, and the third epitaxial layer can be sized and shaped to have at least one of a polygonal or circular cross-section. The first epitaxial layer, the second epitaxial layer, and the third epitaxial layer can be sized and shaped in a vertical column that is tapered toward the first electrode. The first epitaxial layer, the second epitaxial layer, and the third epitaxial layer can be sized and shaped with a geometry configured to constrict ion and electric current flow. In some arrangements, the first epitaxial layer may only consist of LiNbO₂, the second epitaxial layer may only consist of LiCoO₂, and the third epitaxial layer may only consist of LiNbO₂. In other arrangements, the first epitaxial layer may only consist of LiCoO₂, the second epitaxial layer may only consist of LiNbO₂, and the third epitaxial layer may only consist of LiCoO₂.

Semiconductor embodiments can include various doping features. For example, layers can be doped at varying levels (e.g., varying dopant densities) with a first doped level and a third doped level have a positive charge and the second doped level has a negative charge. A first doped level and a third doped level can have a negative charge and the second doped level has a positive charge. Also, epitaxial layers (e.g., a first epitaxial layer, a second epitaxial layer, and a third epitaxial layer) can be doped at varying density levels.

Still yet other semiconductor embodiments can generally include a crystalline substrate and an array variable resistance pillars. The crystalline substrate and a plurality of electrodes can be spaced apart from the crystalline substrate. The array of variable resistance pillars can be disposed between the crystalline substrate and at least one of the electrodes. The array of variable resistance pillars can each comprise at least two layers of epitaxial-metal-oxide semiconductor materials. The semiconductor materials can comprise metal oxide compositions enabling ion/dopant flux through the variable resistance pillars in response to an electric potential. The variable resistance pillars can retain a resistance value as a function of charge associated with the electric potential. Each of the variable resistance pillars can form part of a memory cell, memristor, memdiode, memtransistor, or charge storage device. A semiconductor device can also comprise a network of read/write access lines configured to be in communication with each of the array of variable resistance pillars to enable detection and programming of a resistance value for each of the array of variable resistance pillars.

Semiconductor embodiments including an array of variable resistance pillars can also have additional features. For example, the variable resistance pillars in the array can comprise up to three layers of epitaxial-metal-oxide semiconductor materials, and each of the pillars can be symmetric heterostructures and symmetric heterostructures. Also, the variable resistance pillars can comprise up to three layers of epitaxial-metal-oxide semiconductor materials, and each of the three layers can be a Lithium based metal oxide semiconductor. A network of read/write access lines can be configured to be in communication with each of the array of variable resistance pillars to enable detection and programming of a resistance value for each of the array of variable resistance pillars. The array of variable resistance pillars can write and erase a resistance value without application of a set/reset voltage; this feature is based on the analog memory nature of the utilized materials. The array of variable resistance pillars can have a length ranging from about 10 microns to 100 microns (thus being on the micron scale as opposed to the nano scale).

Semiconductor embodiments including an array of variable resistance pillars can also have further additional features. For example, an electrode can be positioned proximate a substrate and between at least one of the pillars and another other electrode can be positioned proximate an opposing end of the pillars. The distance the electrodes can be greater than about 10 microns (thus being on the micron scale as opposed to the nano scale). The array of variable resistance pillars have a ratio of programmable resistance values equal to or exceeding about 1000:1 from a maximum resistance value to a minimum resistance value. Each of the variable resistance pillars can form part of a memory cell, with each memory cell having an infinite number of data states. Each of the variable resistance pillars can also form part of a memory cell, with each memory cell having more than two data states.

Yet another semiconductor device embodiment generally includes a first variable resistance material and an electrical charge source. A first layer of the first variable resistance material can define a first surface and a second surface opposed from the first surface. The first variable resistance material can be programmable to be one of an n-type or a p-type material. The first layer can comprise material enabling transport of holes and electrons between the first surface and the second surface in response to electric potential. The electrical charge source can be in electrical communication with the first layer to supply the electric potential for programming resistances for the first variable resistance material. A semiconductor device can also include a second layer of a second variable resistance material and a third layer of a third variable resistance material. The second variable resistance material can be programmable to be one of an n-type or a p-type material. The third variable resistance material can be programmable to be one of an n-type or a p-type material. The second and third layers can be stacked on the first layer and in electrical communication to receive electric potential from the electrical charge source. In response to the electrical charge source the layers can transport holes and electrons for programming resistances for the second and third variable resistance materials.

Semiconductor devices that generally include a layer of a first variable resistance material can also include additional features. For example, the first layer, second layer, and third layer can be configured to be programmable to be programmed to an N-type transistor or a P-type transistor in response to charges provided by a electrical charge source. A DC voltage can be applied by the electrical charge source for programming. The first layer, second layer, and third layer can be held in a programmed state by using an AC source for data readout and processing operations. In some embodiments, the electrical charge source is a solar cell configured to convert light into an electric potential for delivery to the first layer.

In some semiconductor embodiments, a single layer of semiconductor material can include a number of sub-layers. For example, the first layer can comprise a plurality of sub-layers. Boundaries between sub-layers can form boundary interfaces, and in response to electric potential, the sub-layers can source or sink ions/dopants to vary the resistance of the first layer. As another example, the first layer can comprise a plurality of sublayers so that the first layer has at least two heterojunctions with ion sources and ion sinks and include source, gate, drain electrodes.

Semiconductor embodiments can also include programmable devices that enable generic devices (e.g., memristors) to be programmed into a desired operational state. For example, a semiconductor device can include first and second layer of a semiconductor material. The second layer of semiconductor material can be programmed to be a memtransistor, and the first layer can be formed to be a memtransistor. The two memtransistors can be arranged in a complementary fashion to form a complementary memtransistor. Also, application of a voltage to source, gate, drain electrodes of a memtransistor can adjust the conductivity of the sublayers and programs the memristor device to be put into a determined operational state. In some embodiments a first layer (of a memristor device that comprises multiple sublayers and electrodes (e.g., FIG. 10)) can be programmable to be at least one of the following devices: (1) a one transistor memristance programmed memory element; (2) a transistor whose gain can be adjusted via memristance effects; (3) a heterojunction transistor in the AMO2 semiconductor family; and (4) a single transistor that can be reconfigured through application of appropriate source/drain/gate voltages to produce any combination of NMOS depletion mode, NMOS enhancement mode, PMOS depletion mode and PMOS enhancement mode electronic behavior.

Still yet other semiconductor devices according to embodiments of the present invention include solar cell devices. Such embodiments can include a solar cell device capable of converting light energy into an electric potential. The solar cell device can comprise a crystalline-Lithium-based semiconductor material. The semiconductor material can comprise Li ions that flux in response to an electric potential. This can enable the semiconductor material to retain a charge based on movement of the Li ions within the semiconductor material. The solar cell and the crystalline-Lithium-based semiconductor material are preferably integrated in a single package. The crystalline-Lithium-based semiconductor material can comprise a plurality of sublayers of crystalline-Lithium-based layers having alternating n-type and p-type charges.

Solar cell embodiments can also include additional features. For example, solar cell devices can have (a) a charging state of operation wherein the crystalline-Lithium-based semiconductor material retains charge due to Li ion movement in response to receiving electric potential from the solar cell and (b) a discharging state wherein Li ions move within the crystalline-Lithium-based semiconductor material to source an electrical charge. The crystalline-Lithium-based semiconductor material can comprise one or more surfaces configured to receive light energy and generate an electric potential.

A method of splitting water, according to some embodiments of the present invention, includes providing a single crystal epitaxial film of a p-type oxide represented by ABO₂ such that A is a lithium cation, B is a cation selected from the group consisting of trivalent transition metal cations, trivalent lanthanide cations, trivalent actinide cations, trivalent p-block cations, and combinations thereof, and O is an oxygen anion, wherein a unit cell of a crystal structure of the oxide composition comprises a first layer comprising a plane of lithium cations and a second layer comprising a plurality of edge-sharing octahedra having a B cation positioned in a center of each octahedron and an oxygen anion at each corner of each octahedron, and wherein the first layer and the second layer of the unit cell are alternatingly stacked along one axis of the unit cell. The method can further include contacting at least a first portion of a surface of the p-type oxide film with water. In addition, the method can include impinging at least a second portion of a surface of the p-type oxide film with a photon to produce an electron and a hole. Further, the method can include moving the electron and the hole to different portions of the first portion of the surface of the p-type oxide film. Still further, the method can include reacting the hole at the first portion of the surface of the p-type oxide film with the water to produce oxygen gas. In addition, the method can include reacting the electron at the first portion of the surface of the p-type oxide film with the water to produce hydrogen gas. In some cases, the method also includes separating the hydrogen gas from the water. If desired, the method can also include collecting the separated hydrogen gas.

Other aspects and features of embodiments of the present invention will become apparent to those of ordinary skill in the art, upon reviewing the following description of specific, exemplary embodiments of the present invention in concert with the various figures. While features of the present invention may be discussed relative to certain embodiments and figures, all embodiments of the present invention can include one or more of the features discussed in this application. While one or more embodiments may be discussed as having certain advantageous features, one or more of such features may also be used with the other various embodiments of the invention discussed in this application. In similar fashion, while exemplary embodiments may be discussed below as system or method embodiments it is to be understood that such exemplary embodiments can be implemented in various devices, systems, and methods. Thus discussion of one feature with one embodiment does not limit other embodiments from possessing and including that same feature.

### BRIEF DESCRIPTION OF THE FIGURES

FIG. 1 is a schematic illustration of the delafossite structure type adopted by some ABO₂ compositions of the present invention.

FIG. 2 is a schematic illustration of the α-NaFeO₂ structure type adopted by some ABO₂ compositions of the present invention.

FIG. 3 is another schematic illustration of the α-NaFeO₂ structure type adopted by some ABO₂ compositions of the present invention.

FIG. 4 is a schematic illustration of the structure of LiNbO₂ in accordance with some embodiments of the present invention.

FIG. 5 graphically illustrates a multi-layer epitaxial stack that can be used in a process to fabricate a memristor device in accordance with some embodiments of the present invention.

FIG. 5A illustrates a layer stack embodiment comprising access or address lines in accordance with some embodiments of the present invention.

FIG. 6 graphically illustrates a memristor device in accordance with some embodiments of the present invention.

FIG. 6A illustrates a layer stack embodiment comprising access or address lines in accordance with some embodiments of the present invention.

FIG. 7 graphically illustrates another memristor device in accordance with some embodiments of the present invention.

FIG. 8 graphically illustrates another memristor device in accordance with some embodiments of the present invention.

FIG. 9 graphically illustrates a multi-layer epitaxial stack that can be used in a process to fabricate a memristor device in accordance with some embodiments of the present invention.

FIG. 10 graphically illustrates a transistor device in accordance with some embodiments of the present invention.

FIG. 11 schematically illustrates a radial electrode for use with a memristor cell in accordance with some embodiments of the present invention.

FIG. 12 schematically illustrates a memristor cell in concert with a cross-bar access arrangement in accordance with some embodiments of the present invention.

FIG. 13 graphically depicts how a complementary (n-type/p-type) memristor's resistance can change (increasing or decreasing) in time as an electric field is applied.

FIG. 14 schematically illustrates a memristor array that can include a plurality of the various memristance cell devices herein in accordance with some embodiments of the invention.

FIG. 15 schematically/graphically depicts embodiments of (from upper left to lower right), p-channel enhancement, n-channel enhancement, p-channel depletion, and n-channel depletion LiNbO₂ MISFET. Current/voltage curves with threshold voltages are also illustrated.

FIG. 16 schematically illustrates an exemplary solar cell semiconductor device in accordance with some embodiments of the present invention.

### DETAILED DESCRIPTION

Embodiments of the present invention generally include novel metal oxide materials and a variety of devices incorporating the materials. The oxide materials include compositions, films, and methods of fabricating the materials. The materials can be used to implement and make a variety of devices. Devices and end uses include, for example, but are not limited to, memristors, neuromorphic computing, photoelectrolytic-hydrogen-generator cells, solar cells, batteries, memory cells, semiconductor devices, transistors, and devices that combine any number of these functions such as battery storage solar cells and transistors with inherent memory.

For ease of discussion, the detailed description section of the application is broken into several sections to discuss the novel materials, fabrication methods, and devices. Several of these sections also include disclosure on various applications of implementing the novel materials which are included within the broad scope of this disclosure. Drafting in sections is done to help the reader understand the many applications and uses of the metal oxide materials. As mentioned above, and while there are certain sections in this application, aspects and features discussed in one section of the application can also apply to any other section as certain features may be related across end use applications.

### Novel Oxide Structures & Fabrication Methods

The improved semiconductor oxide compositions of the present invention are based on the general formula ABO₂, wherein A is a monovalent cation, B is a trivalent cation, and O is an oxygen anion. In general, the unit cell of the crystal structure is characterized by layers of A-site cation planes that are alternatingly stacked with layers of edge-sharing octahedra having the B-site cation positioned in the center of each octahedron and oxygen anions at the corners of each octahedron.

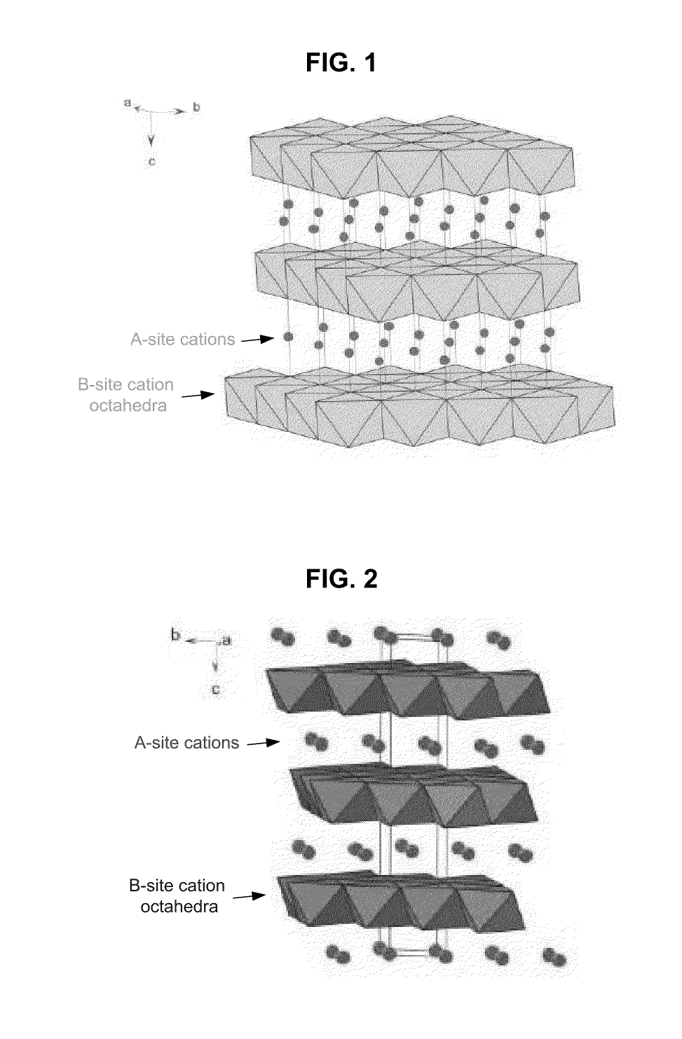

One such structure is the delafossite structure, which is shown in FIG. 1. The delafossite structure generally accommodates copper (Cu), silver (Ag), palladium (Pd), and platinum (Pt) as the only A-site cations, along with any B-site cation having an ionic radius of about 0.535 Angstroms to about 1.03 Angstroms. As shown in FIG. 1, delafossites, or delafossite-like materials (i.e., those adopting the same structure as the mineral delafossite), have each A-site cation linearly coordinated to two oxygen anions of the edge-sharing octahedra (one of which is in the layer above the A-site cation, and the other of which is in the layer below the A-site cation). Such materials can have the unique ability among oxides to exhibit both n-type and p-type conductivity in their native forms.

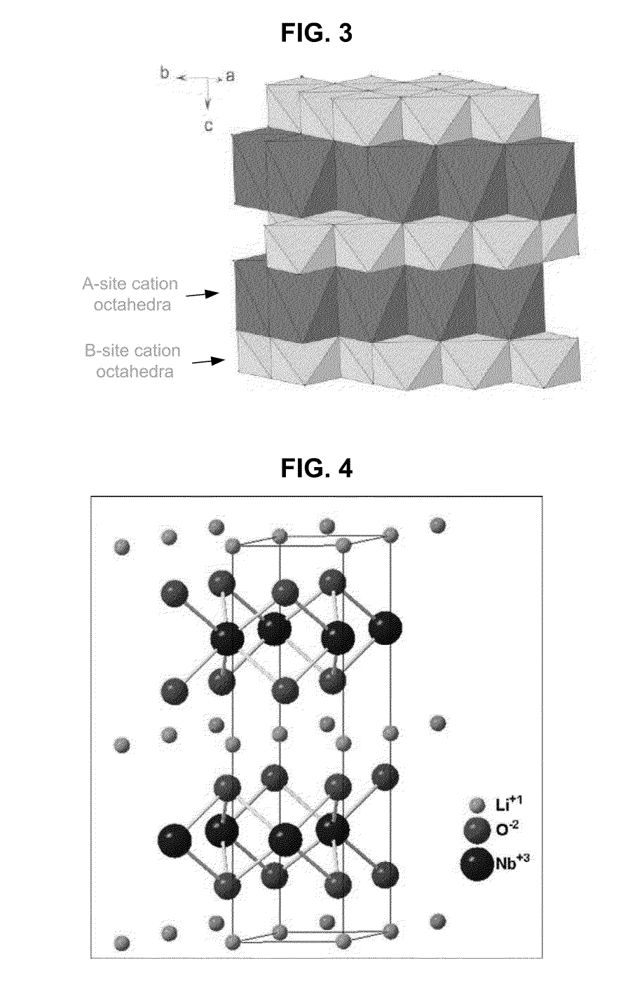

Another such structure is the so-called “α-NaFeO₂” structure, which is shown in FIGS. 2 and 3. In this structure type, the A-site cation is generally smaller than those A-site cations that can adopt the delafossite structure. Exemplary A-site cations for the oxide compositions of the present invention include sodium (Na) and lithium (Li). As a result of this smaller size, the A-site cations in this structure type do not sit directly/linearly below or above an oxygen anion as they do in the delafossite structure. Rather, each A-site cation has three nearest-neighbor oxygen anions both above and below it, as seen in FIG. 2. Thus, each A-site cation effectively serves as the center of an octahedron, which shares an edge with a neighboring octahedron. This packing is shown in slightly different format in FIG. 3 for illustrative convenience. These materials can also have the ability to exhibit both n-type and p-type conductivity in their native forms.

One exemplary class of ABO₂ compositions of the present invention are those where the A-site cation is Li. In some cases, these LiBO₂ or, alternatively, “LiMO₂” compositions adopt the α-NaFeO₂ structure type. In other cases, however, these compositions adopt a different structure type, which has the same general alternatingly-stacked-layer motif as both the delafossite structure and the α-NaFeO₂ structure but has some localized distortion, level of disorder, or the like that renders it a different structure type than either the delafossite structure or the α-NaFeO₂ structure. For example, the B-site cation-containing octahedra can be slightly distorted such that the B-site cation is not at the exact center of an octahedron and/or one or more of the axes of the octahedron can be elongated to provide a different crystal structure. Manganese (Mn) in the trivalent state is one such cation that undergoes such distortions.

In general, the B-site cation (or the “M”) can be any trivalent cation that will not substantially disturb the planarity of the Li ions or the alternatingly-stacked-layer motif. Thus, the B-site cation generally can be chosen from the transition metal series, lanthanide series, the actinide series, p-block metals, and combinations thereof (i.e., such that a solid solution is formed). It should be noted that the use of some cations, of which iron (Fe) is one, will produce a structure that does not have the desired alternatingly-stacked-layer motif, but when implemented in combination with another cation to form a solid solution (e.g., represented by LiM₁₋ₓFeₓO₂ where x<1) will produce the desired structural motif. Also, some cations will be capable of producing multiple structure types for the same composition, where less than all of these structure types will have the desired structural motif. An example of such a cation is aluminum (Al), which can produce an α-, β-, and γ-LiAlO₂ structure, but only the α-form has the desired structural motif; as such, only the α-form is contemplated for use by the embodiments of the present invention. Specific, non-limiting, examples of B-site cations include niobium (Nb), cobalt (Co), nickel (Ni), Fe, lanthanum (La), Mn, scandium (Sc), Al, gallium (Ga), indium (In), rhodium (Rh), chromium (Cr), yttrium (Y), and europium (Eu).

For integration in the devices and end uses listed above (and described below in more detail), it will sometimes be necessary to produce such oxide compositions in film form. Desirably, the films of these oxide compositions will be single crystal films. Single crystal film growth, particularly epitaxial growth, of materials involving the cations of the oxide formulations of the present invention has been difficult to achieve.

For example, molecular beam epitaxy (MBE), while capable of producing high-quality epitaxial layers in many material systems, is normally limited to the growth of semiconductors with moderate-to-high vapor pressure (Pᵥₐₚ) elemental constituents (e.g., Pᵥₐₚ on the order of about 1×10⁻³ torr or greater for temperatures of about 1200° C.) owing to the limitations of obtaining sufficient growth flux from low vapor pressure sources such as refractory metals. While it is possible to use metal-organic precursors with MBE in, such as with metal organic molecular beam epitaxy (MOMBE), difficulties with pre-reaction and carbon contamination make this approach less straightforward than solid-source MBE. Evaporation via electron-beam (e-beam) heating is another method to supply refractory metals in MBE. A standard e-beam source, however, is a less stable source of flux than a thermal cell, and e-beam components, particularly the glowing filament and the hot carbon crucible, are less compatible with an oxygen environment than a standard effusion cell. While the above discussion has centered on MBE-based techniques, it would be understood to those skilled in the art to which this disclosure pertains that the same or similar difficulties are encountered in trying to grow oxide compositions having refractory metal cations using other single-crystal film growing techniques.

Improved methods of fabricating single-crystal thin films of the ABO₂ compositions of the present invention involve the use of halide-based precursor chemistries for films grown by MBE, chemical vapor deposition (CVD), atomic layer epitaxy, and the like. These techniques are particularly beneficial for refractory metal-containing films Like metal-organic precursors, metal-halide-based materials are able to readily produce growth level fluxes (e.g., a beam equivalent pressure (BEP) on the order of about 1×10⁻⁶ torr) at temperatures more commonly used in MBE (e.g., about 30° C. to about 700° C.). An advantage of metal-halide-based precursors, and particularly chloride-, bromide- and iodide-based precursors, is that they do not generate the hydrogen and carbon contamination associated with metal-organic precursors. Additionally, with metal-halide precursors, there is enormous flexibility in film component choices (i.e., in part because almost all refractory metals are available as a solid halide composition). As an added benefit, many metal halides are available in higher purity than in elemental form.

These methods are especially beneficial when a Group I metal is the A-site cation of the ABO₂ composition. The Group I metal (e.g., Li, Na, or potassium (K)) can serve as a reducing agent to dissociate the halide ion from the metal-halide precursor, leaving the metal behind for forming the desired film. By way of illustration, when Li is the A-site cation (or, in the case of a solid solution, one of the A-site cations), excess Li can be used as a reducing agent. In this manner, only the metal remains behind after a volatile Li-halide byproduct is desorbed from a substrate, which occurs when the substrate temperature is sufficiently high (e.g., about 500° C. to about 1000° C.) so as to preferentially evaporate the higher vapor pressure Li-halide compound and leave the extremely low vapor pressure metal behind.

In these cases, the stability of the metal halides, in conjunction with the ability of the Group I metal to serve as a reducing agent at the substrate, enables the metal halides to be transported readily through tubing, mass flow meters/controllers, and other film-growing equipment without the need for direct line-of-sight evaporation as in traditional MBE. Only after the Group I metal reducing agent comes into contact with the metal-halide source will the elemental metal result.

In general, by controlling the various ratios between the oxygen, B-site cation precursor, and the A-site cation precursor, the stoichiometry of the films can be controlled. In addition, when the ABO₂ composition is capable of exhibiting both n-type and p-type conductivity in its native form, then these ratios can be manipulated to control the level of doping in the composition.

Taking the case of LiMO₂ for example, by fabricating the film to have Li vacancies or deficiencies (i.e., relative to the stiochiometric case), the materials can exhibit p-type conductivity. The amount of Li in such compositions can be reduced simply by using less Li flux so as to render removal of the halide from the B-site cation metal-halide precursor more difficult. Conversely, the introduction of additional Li flux allows the LiMO₂ composition to be formed with an increased Li concentration (i.e., closer towards, or at, the stiochiometric case). As a result, p-type LiMO₂ films having a wide range of carrier concentrations can be grown using these techniques. In fact, in some cases, up to about half of the Li sites in the LiMO₂ structure can be vacant without distorting the crystal structure (e.g., to an undesirable spinel or other structure).

In contrast, by incorporating oxygen deficiencies or vacancies in the films, the materials can exhibit n-type conductivity. The amount of oxygen in such compositions can be reduced by reducing the flow of oxygen gas into the growth region. As was the case with Li above, the introduction of additional oxygen allows the LiMO₂ composition to be formed with an increased oxygen anion concentration (i.e., closer towards, at, or even above the stiochiometric case). As a result, n-type LiMO₂ films having a wide range of carrier concentrations can be grown using these techniques. In fact, in some cases, up to about 10 percent (%) of the oxygen anion sites in the LiMO₂ structure can be vacant without distorting the crystal structure.

Thus, in addition to traditional post-growth de-intercalation or ion exchange techniques that can be used to remove Li cations or oxygen anions, these methods enable fabrication of highly-intrinsically doped oxide compositions of each polarity (i.e., n-type or p-type). Alternatively, or in addition, these compositions can be extrinsically doped as desired. This can be accomplished during growth, by introduction of additional cation or anion sources in sufficiently-low concentrations so as to not produce a film with an undesirable crystal structure, or post-growth using known diffusion, implantation, or exchange techniques.

To illustrate the methods described herein, reference will now be made to the growth process for a LiNbO₂ film. The crystal structure of this material is shown in FIG. 4. This structure mimics the α-NaFeO₂ structure type more so than the delafossite structure in terms of the oxygen anion coordination environment. In contrast to the α-NaFeO₂ structure, however, the unit cell of LiNbO₂ shown in FIG. 4 has three planes of oxygen anions rather than four such planes.

Growths were performed on a Varian Generation II MBE system extensively modified for oxide epitaxy. Source materials were elemental lithium from ESPI Metals, NbCl₅ from Alfa Aesar, and various oxygen species generated by an SVT Associates SVTA plasma source.

The Nb precursor, NbCl₅, existed as the dimer Nb₂Cl₁₀ in the solid state and in equilibrium with the monomer in the vapor state under standard operating conditions. Niobium chloride has a calculated (using the HSC® thermodynamic modeling software) equilibrium vapor pressure of about 1×10⁻⁴ torr at about 20° C. Elemental niobium requires a temperature of about 2300° C. for the same equilibrium vapor pressure, and thus would require e-beam evaporation, which would have been problematic in an oxygen environment, and typically has a flux drift of 2-5%. The high vapor pressure of the chloride allowed a flux of Nb sufficient for a deposition rate of about 1 to about 5 micrometers per hour (μm/hour) at a cell temperature of about 4° C. The high vapor pressure of the NbCl₅ enabled the use of an oil-heated (Createc NATC-40-40-290), low-temperature organic effusion cell to provide the temperatures needed for growth fluxes, with a temperature controllability of about 0.1%.

The lithium was supplied by a heavily modified Veeco corrosive series antimony cracker, the modification being to contain a custom-made 200 cc tantalum crucible. The large-volume cell body was heated from about 450 to about 600° C. during operation with the flux controlled by an integral valve so as to further stabilize the Li flux by ensuring near perfect Knudsen operation.

Aside from passivation with Li vapor and the utilization of corrosion resistant materials, a third way to limit any potential damage from chlorine and/or oxygen was to limit the absolute amount of reactive species encountered. As such, the reflection high-energy electron diffraction (RHEED) electron gun filament was isolated. A differential pumping system was designed with an orifice of about 1 millimeter (mm) placed in front of the filament to allow electrons to pass. This pumping manifold maintained a 2 order-of-magnitude pressure differential across the orifice, which increased RHEED filament lifetime.

The oxygen source was an SVTA plasma source with O₂ flow controlled by a MKS mass flow controller. The plasma supply operated in a high brightness, inductive mode at about 400 watts (W) forward power and 0 W reflected power. The O₂ flow was set between 1 and 2 standard cubic centimeters (sccm) and was held constant during the growth.

The substrates used were 4H and 6H (0001)-oriented silicon carbide wafers with epitaxial SiC layers of thicknesses from about 1 to about 3 micrometers and (0001)-oriented sapphire. In theory, any substrate that provides a sufficiently-low lattice mismatch (e.g., less than about 1%, and, in some cases, less than about 0.01%) can be used. Use of epitaxial SiC circumvented the difficulty of achieving proper surface preparation normally encountered for polished and/or hydrogen etched substrates and provided terraces useful in rotational registration of the island nucleated films common to lattice mismatched epitaxy. The wafers were diced into dies of about 1 centimeter (cm)×1 cm. Sample preparation began with a two-step solvent clean, first acetone then methanol, to remove photoresist, followed by a deionized water rinse. Next, two successive piranha cleans were performed at about 120° C. for about 10 minutes, with a deionized water rinse at the end of each clean. Finally, a hydrofluoric acid (HF) etch was used to remove any oxide layer on SiC dies.

The substrates were placed into the vacuum load lock and outgassed at about 250° C. for about 1 hour after which in-situ titanium evaporation was performed on the wafer back side to promote efficient absorption of the radiation from the substrate heater. The wafers were then transferred into the growth chamber and brought to about 950° C. as measured by an adjacent, non-contacting thermocouple. Flux measurements were taken for the solid sources. Once the substrate temperature was stable, the oxygen plasma was ignited and the growth was started. After growth, all cells were closed, but the oxygen remained incident on the sample. The sample was cooled to about 150° C. under the oxygen plasma. It was found that at the growth conditions, no oxidation of the SiC resulted.

X-ray diffraction (XRD) analysis was performed on a Philips PW3040 Pro MRD X-ray system. A Tencor Alpha-Step Profilometer was used to measure the film thickness at clip marks on the sample corners. Electrical measurements were also performed to determine surface resistivity, mobility, and carrier concentrations using a custom setup with a Keithley 7001 switch matrix, 2182A nano voltmeter, 485 pico ammeter, 6211 DC & AC current source with custom Labview software. An Atomika Ionprobe A-DIDA SIMS was also used to profile the lithium, niobium, and silicon concentrations in some of the films and to confirm no detectable residual chlorine present. A Veeco Dimension 3100 Atomic Force Microscope (AFM) was used to determine surface roughness.

Selected samples were annealed in a MILA-3000 Rapid Thermal Annealer (RTA) continually purged with oxygen. Anneal temperatures ranged from about 200° C. to about 700° C.

Using this growth process, to the inventor's knowledge, the first epitaxial growth of single-crystal lithium niobite films (LiNbO₂) was achieved. White light transmission spectroscopy of these films confirmed a 2.0 eV band gap. The as-grown films were semiconducting with absorption characteristics consistent with a well-behaved “classic semiconductor” with parabolic energy bands. The structural quality of LiNbO₂, determined by XRD, rivals more mature lattice-mismatched semiconductor technologies such as III-Nitrides with a full-width half-max (FWHM) of about 270 arcsec.

Capacitance voltage measurements indicate substantial lithium drift at room temperature. This means that, a memory effect was present in LiNbO₂. The lithium drift in LiNbO₂ caused a measurable change in the conductivity. N-type and p-type LiNbO₂ films were grown. The n-type LiNbO₂ was capable of being converted to p-type by de-intercalation of lithium. The LiNbO₂ films demonstrated n-type conductivity as high as about 1700 S/cm and p-type conductivity as high as about 2500 S/cm, which appears to be the highest p-type conductivity reported in an oxide semiconductor. This high conductivity is in part due to its hole concentrations exceeding about 1×10²¹ cm⁻³ and a mobility over about 8 cm²/V·s.

In another illustration of these methods, films of LiCoO₂ were similarly grown, only using CoCl₂ as the Co precursor. These and other LiMO₂ films, as-grown, of native oxides can exhibit n-type and p-type conductivities of over 1000 Siemens per centimeter (S/cm). In some cases, the oxide material can have sufficient crystallinity to exhibit bipolar conduction exceeding 2000 S/cm in each of the n-type or p-type configurations. Some of these films can exhibit minority carrier lifetimes of over 1 microsecond. It is these electrical properties that can be taken advantage of to provide the various devices described below.

### Metal Oxide Based Memristors

Embodiments of the present invention include memristors formed from the ABO₂ oxide materials described above. Element A is currently preferred to be Li. In other embodiments, A could also be Cu, Ag, Au, Hg, H, Na, K, Rb, or Cs. B can be any metal cation or combination of cations with an oxidation state of 3+, including but not limited to, Nb, V, Al, Ga, In, Co, Ti, Sc, Y, Cr, Mo, W, Re, Fe, Ru, Os, Rh, Ir, Tl, Ni, Mn, any from the Lanthanide series and actinide series.

According to some embodiments of the present invention, it is believed that memristor discussed herein are advantageous due to the single crystal materials used to fabricate the devices. Such crystal material yields low resistance devices capable of having large ranges of resistance thereby enabling stored resistance values to be large also. As will be discussed below such large resistance range values provide advantageous memory storage capabilities, charge storage abilities, and also capabilities to program generic memristors to desired operational states based on application of bias charges.

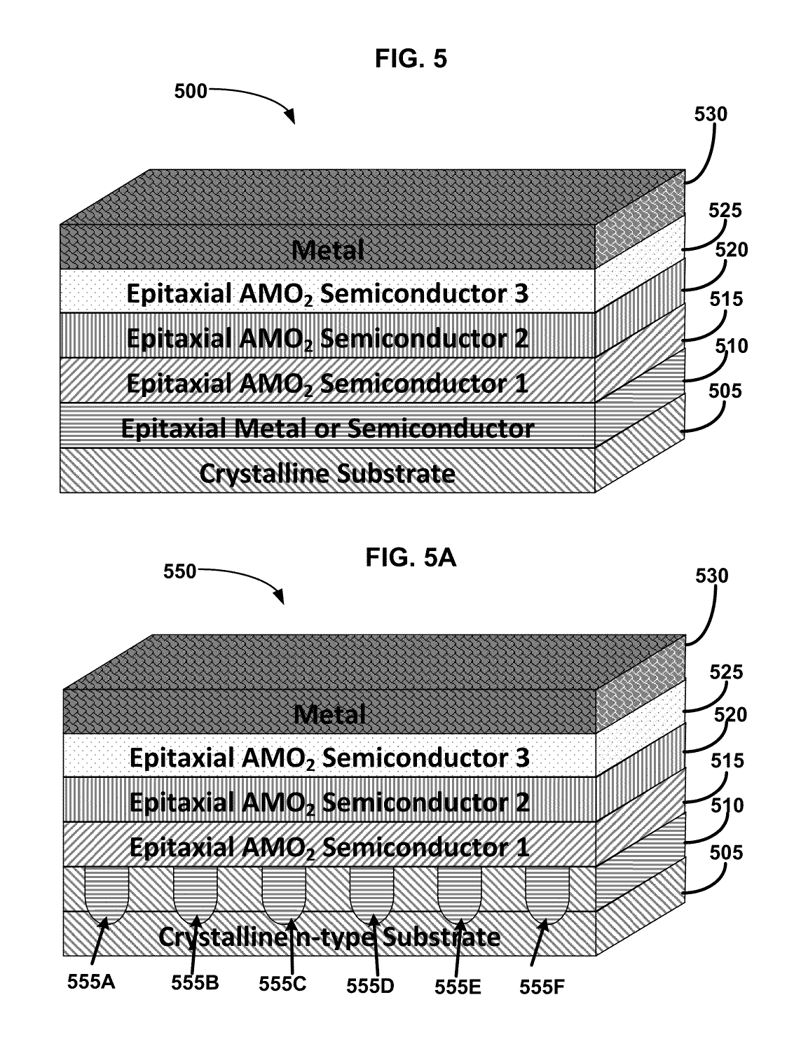

Turning now to FIG. 5, it illustrates a perspective side view of a multi-layer epitaxial stack 500 that can be used in a process to fabricate a memristor device in accordance with some embodiments of the present invention. The stack 500 can itself be a vertical memristor cell as well as an intermediate product in a fabrication process to create other shaped memristor cells. The stack can be formed via various processes, including MBE and CVD deposition. The stack 500 can also represent a starting point in a fabrication process, and as is illustrated, include the layering of various materials.

While currently preferred memristor embodiments include epitaxial layers, some embodiments can be made via other fabrication processes. The discussion in this application when discussing layers includes the stacking of various material layers in a linear or vertical stack. The shape of the layers, however, can vary and include many possible arrangement, geometries, and shapes. Arrangements can vary from tapered to planar to offset. Geometries can include both curved and polygonal. Shapes can include pillar-type shapes, conical-type shapes, and cylindrical-type shapes. Several exemplary shapes are shown in FIGS. 5-10 and discussed in more detail below.

As shown in FIG. 5, the stack 500 can include a variety of build up layers. These layers can include a substrate layer 505, a metal/semiconductor layer 510, metal oxide layers 515, 520, 525, and a metal layer 530. In some embodiments, the metal oxide layers 515, 520, 525 may be combined in two or one layers. All of the layers together can enable the stack to function as a memristive device. This can be done as the materials making up the layers can include ions that can move within or across layer boundaries to vary the resistance of the layers. This activity enables the layers to have variable resistance as a function of the amount of electrical charge applied to the layers. While illustrated in FIG. 5, in some embodiments layer 510 is optional; for example, layer 510 is optional for a memtransistor structure (discussed below) or for a lateral memristor (i.e., any device that has all top contacts/electrodes). In some embodiments, the metal/semiconductor layer 510 in concert with the metal layer 530 can be configured to supply an electrical charge (voltage or current) to the metal oxide layers 515, 520, 525.

The metal/semiconductor layer 510 and the metal layer 530 are preferably epitaxial layers although they can be made with other fabrication processes. If 515 and above layers are crystalline, layer 510 is preferably crystalline (epitaxial). As mentioned above, the substrate 505 and metal layer 530 can be sized and shape to function as electrodes so that a potential can be applied across the stack 500 to enable ion flux (as discussed in more detail below). In some embodiments, layer 510 can be made of any number of epitaxial metals, including but not limited to, Nb, V, Al, Ga, In, Co, Ti, Sc, Y, Cr, Mo, W, Re, Fe, Ru, Os, Rh, Ir, Tl, Ni, Mn, any rare earth element from the Lanthanide series, and U. Epitaxial Fe can be applied to two substrates and epitaxial Nb can also be used. Some currently preferred embodiments include epitaxial single crystal orientation and smooth planar surfaces. Either material or others above, can be used for layer 510. Electrode layer 530 may be an epitaxial metal or alternatively a simple polycrystalline/amorphous metal layer as it, being the top layer in the stack 500, serves no need for further crystalline templating functionality.

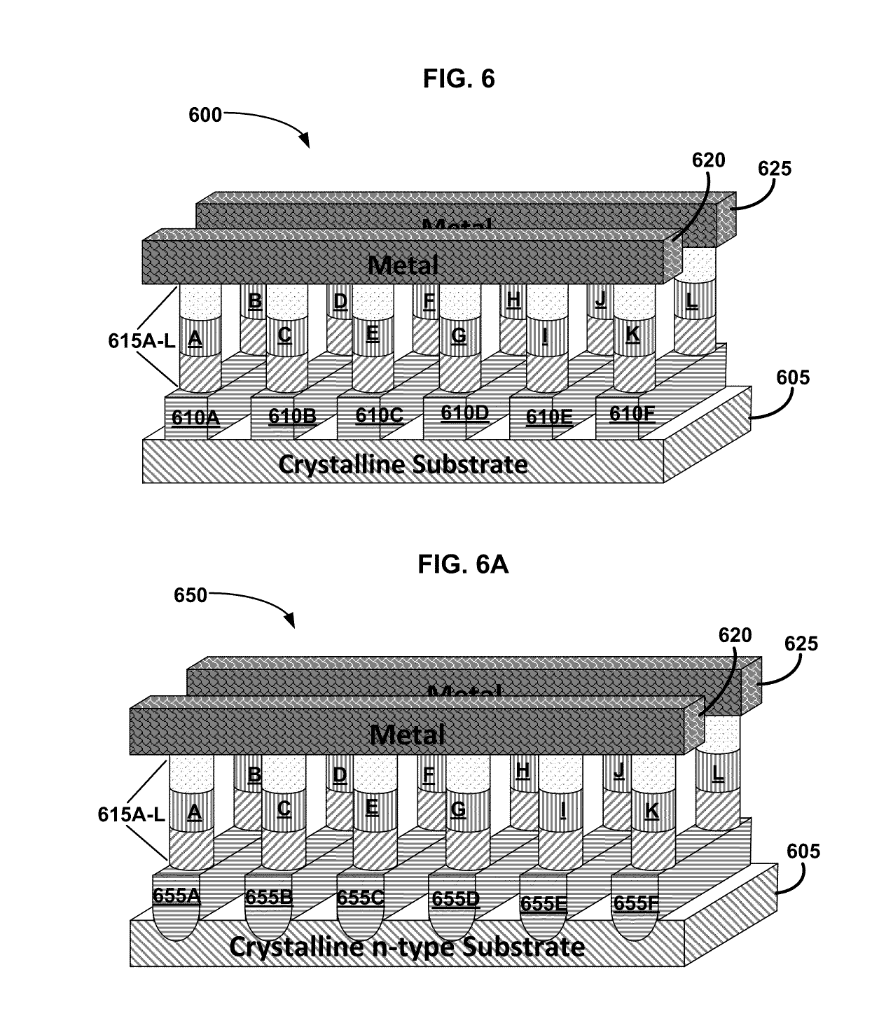

Epitaxial metal layers offer several advantages. One advantage is being able to maintain low resistance (as compared to a doped semiconductor option shown in FIGS. 5A and 6A) access to the individual devices but also retain the single crystalline crystal structure needed to template the epitaxial growth of the metal oxide layers 515, 520 and 525. Since many AMO₂ compounds are constructed from sub-oxides, depositing an epitaxial layer as layer 530 after all other layers are completed but before the device sees atmosphere has the advantage of stabilizing the chemistry of the material/device and preventing any surface degradation due to exposure to the atmosphere.

The metal oxide layers 515, 520, 525 can be doped to have p-type or n-type characteristics thereby enabling the stack 500 to function as a semiconductor. Depending on the device application, the thickness of the layers can be a few nanometers up to a few microns. For example, when making a memristor or a transistor with memory, the layers may be a few nanometers whereas when making a solar or photoelectrolytic cell the layers may need to be a few microns.

In some embodiments, the metal oxide layers 515, 520, 525 can be epitaxial (crystalline) layers of semiconductors having symmetric heterostructures. In an exemplary symmetric heterostructure arrangement with a three layer stack, the outer layers can be of the same composition or polarity and the inner layer can be of a different composition or polarity. For example, the metal oxide layers 515, 520, 525 can be formed in the following layer arrangements: LiNbO₂/LiCoO₂/LiNbO₂ or LiCoO₂/LiNbO₂/LiCoO₂. In a more general arrangement, the metal oxide layers 515, 520, 525 may be formed with metals having the following formulations: LiNbₓCo₁₋ₓO₂ and LiNb_{y}Co_{1-y}O₂ where x>y to indicate allowable and variable heterostructure bandgaps. Similarly, alloys of different B-site atoms can be used as well.

The symmetric metal oxide layer arrangements can be useful for AC voltage and current sensing (DC or asymmetric pulse programming). An alternating Nb/Co structure can provide a heterostructure with a 0.5 eV offset. This can be useful for providing activation energy that results in a turn on voltage in a memristor cell. By providing heterojunctions, a measure of electrical rectification can be designed to produce any electronic (electron/hole) current voltage characteristic varied from linear (resistive) to fully rectifying (diode) while still using ionic conduction for varying the electronic property (e.g., between a memristor or a memdiode).

The metal oxide layers 515, 520, 525 epitaxial (crystalline) layers can also be asymmetric. In an asymmetric arrangement, two adjacent metal oxide layers are made from the same material and a third layer is made from a different material. For example, in one arrangement, the layer stack could include metal oxide layers 515, 520, 525 as: LiCoO₂/LiNbO₂/LiNbO₂ or LiCoO₂/LiCoO₂/LiNbO₂ An asymmetric arrangement can make it easier to program ion drift (e.g., Li ion drift) in one direction versus another in response to application of an electric charge source (e.g., opposing contacts or end electrodes). An asymmetric structure can also provide devices that provide “write once” memory or alternatively use asymmetric write/read voltages.

In some embodiments, the metal oxide layers 515, 520, 525 can be an alloy with fixed or graded composition. For example, the layers can be made of LiNbO₂/LiNbₓCo₁₋ₓO₂ or LiCoO₂/LiFe_{y}Nb_{1-y}O₂ where x and y are either constant with position or vary with position.

Additional to both the symmetric and asymmetric varieties of structures defined by heterostructural bandgap variations that enable tailoring of electronic (e.g., current and/or voltage) properties, structures that act as ion (A site) sources, sinks and barriers can be included in a layer stack. For example, the structure LiNbO₂/LiNiO₂/LiNbO₂ takes advantage of the known lower mobility/diffusivity of LiNiO₂ to provide a Li barrier while still allowing electronic (electron/hole) conduction. Since the ions that are drifted under applied voltage during the programming cycle will have a tendency to partially relax back under no bias (retention cycle) due to ion diffusion, the use of ion barriers also allow for tuning the lifetime of memory effects to implement short term memory and long term memory.

In yet additional embodiments, bipolar layer materials can also be used in concert with, in the place of, or to supplement the compositionally varied metal oxide layers 515, 520, 525. This can be done by doping material layers either n-type or p-type dopants. In one example, a bipolar arrangement can include p-type LiNbO₂/n-type LiNbO₂ in symmetric and asymmetric as well as homojunction and heterojunction configurations. Each of the n-type and p-type layers can implement a memristor whose resistance will increase (n-type) or decrease (p-type) with applied voltage. Having bipolar heterojunctions can increase device activation energy making the turn on voltage of memdiodes higher but in general, tunable by polarity and heterojunction selection. Using these type of structures facilitates implementation of diodes useful for 1D1R (one diode 1 resistor) memory cells, rectifiers, solar cells and water splitters (photoelectrolytic cells), all with added benefits of ion storage and motion.

In diode embodiments, the turn on voltage and electrical breakdown characteristics are generally determined by the relative energy band offsets between a cathode and an anode. In nN or pP heterostructures (where n is the small bandgap n-type material and N is the larger bandgap n-type material—similarly for p-type materials p and P), the turn on voltage, electrical breakdown voltage, and thus the diodes ability for rectification are limited by the energy band offset. For example, in the previous example, a LiNbO₂/LiCoO₂ heterostructure can have 0.5 eV of rectification (much less in practice due to well known “band alignment effects”) due to the limited difference in energy bandgaps, 2 eV for LiNbO₂ and 2.5 eV for LiNbCoO₂. If, however, one uses a bipolar heterojunction such as n-type LiNbO₂/p-type LiCoO₂, the diode's activation energy can be as high as 2 eV to 2.5 eV depending on several factors, including doping characteristics and electron affinity.

As shown in FIG. 5, the stack 500 includes substrate layer 505 and metal/semiconductor layer 510. These layers can aid in enabling memristor cell functionality. In currently preferred embodiments, memristor structures depend on high crystalline quality. The high crystalline quality consists of single orientations of materials as quantified by x-ray diffraction and crystallographic examinations obtained by growing epitaxial semiconductor structures on crystalline substrates. Thus substrate layer 505 can be made with sapphire, silicon, LiNbO₃, LiTaO₃, silicon carbide or bulk (many microns to millimeters in thickness) crystals of the ABO₂ crystal class. High quality epitaxial single crystalline metals of Nb, Fe, and Co may also be used. Thus, insulating substrates (e.g., sapphire, LiNbO₃ or LiTaO₃) can be used in combination with grown and patterned epitaxial metals.

In some embodiments, utilized substrates can be configured with memristor cell access (or address) lines. FIGS. 5A and 6A illustrate layer stack embodiments comprising access or address lines. FIG. 5A shows a variant of the stack 500 that includes patterned access lines 555A-F. FIG. 6A is a variant of FIG. 6 (discussed below in more detail) that includes patterned access lines 655A-F. The patterned access lines 555A-F, 655A-F can be patterned during fabrication and can be fabricated with either or both epitaxial metal and/or semiconductor materials.

The access lines are more general and include other arrangement and mechanisms enabling contact or electrical communication with each individual memristor elements of an array. In some embodiments, the access and address lines can be fashioned as word and bit lines in a digital implementation or merely as interconnect lines in an analog application. Use of access lines, like access lines 555A-F, 655A-F, enables access to memristor cells for memory and programming operations (e.g., resistance programming, memory write, and memory read). As shown in FIGS. 5A and 6A, a substrate can be a semiconductor (e.g., Si or silicon carbide) and include access lines made from opposite polarity doping. In other words, patterned p-type layers on an n-type substrate or patterned n-type layers on a p-type substrate. This opposite polarity doping in the patterned access lines verses a substrate provides electrical isolation from the substrate. If the substrate is a semiconductor, further isolation can be enhanced by reverse biasing the access-line/substrate junction.

FIGS. 6 and 6A illustrates a perspective view memristor devices 600, 650 in accordance with some embodiments of the present invention. The devices 600, 650 generally include a substrate 605, a plurality of rectangular-shaped cross bars 610A-F, a plurality of cylindrical columns 615A-L, and dual top electrodes 620, 625. The devices 600, 650 can be made by etching the stack 500 so that the components illustrated in FIGS. 6 and 6A are sized and shaped as illustrated. FIG. 6A illustrates a memristor device 650 similar to device 600 and includes patterned access lines 655A-F (as mentioned above). Etching of the layers in the stack 500 can result in the shapes of the rectangular-shaped cross bars 610A-F, the plurality of cylindrical columns 615A-L, and the dual top electrodes 620, 625.

The cylindrical columns 615A-L can be memory cells in the memristor devices 600, 650. As discussed herein, memory cells may also be referred to as memristor cells or cells. The memory cells 615A-L can hold a resistance value to enable the cylindrical columns to store data. The resistance value can be programmed and can represent a data state. Data is stored in response to potential applied across the memory cells 615A-L as ion distributions that affect the doping and resistance of the cells in the cylindrical columns 615A-L with the cells reacting to applied potential. This is enabled by the layering of several layers within the cylindrical columns. In currently preferred embodiments, the layers making of the cells 615A-L can include multiple epitaxial semiconductor layers like those discussed regarding FIG. 5 (i.e., layers 515, 520, 525). Stored or programmed data residing in memristor cells 615A-L can be accessed by reading or sensing a resistance from the cylindrical columns 615A-L.

An advantageous feature of memristor embodiments according to the present invention is that memristor devices can be used as analog memory devices. This means that the memory devices can store multiple data ranges beyond the conventional digital 0 or 1. In other words, memory cells according to the present invention are not limited in holding only two finite data values (e.g., on and off states) but rather can hold any number of values (e.g., an infinite number of data states). Due to this advantage, memristor devices according to the present invention can be used in concert with both analog and digital computers/memory devices. Indeed, by using analog memory devices it is possible to weight-store data with priorities. This can be accomplished, for example, by establishing a memory cell weighting rate each time a memory cell is exposed to particular stimulus.

Another advantage of memristor embodiments of the present invention relates to reduction of memory size. For example, if one desires to permanently remember (represent) a “16 bit” number with digital memory it requires at minimum 16 “digital memristors,” or in present technology (e.g., CMOS) 96 transistors (i.e., 16 cells of SRAM with 6 transistors per cell—noting that SRAM is not truly permanent as it is volatile and must be continually refreshed). With an analog memristor one memristor which can store any number of values, including a 16 bit number. Stored values can be accessed by applying a “reading voltage” to an analog memory cell which produces a current. The produced current represents the stored data. An AC reading (or sensing) voltage is currently preferred as this does not affect the state of stored data.

By using a reading (or sensing) voltage, memristor embodiments of the present invention do not require the use of set/reset voltages in existing memristor devices. Also for analog memristors, writing of or programming information can occur with any DC voltage without the need for a set/reset voltage as generally required in digital memristor counterparts.

As mentioned above, analog memristors according to the present invention enable the weighting of stored data for prioritization abilities. This can be achieved via the use of varying programming voltages. For example, 1 mV DC will begin to slowly drive ion motion whereas 1 V DC will drive ion motion faster. In this way, memories can be prioritized with “important” memories (things desired to have permanent and strong memory recovery) strongly embedded in the memristor array and “lesser important” memories (example things used only for temporary processing with no need for permanent storage) requiring repeated exposure to establish permanency (large resistance changes). Prioritization of data stored in memory can aid in providing and meeting nueormorphic computing applications.

Analog memristor devices also have low power consumption benefits as well. As an example, memory reading can be accomplished with 1V AC (AC is preferred so as to not affect the memory state) or 1 nV. Either value will drive a current which can represent the memory state but the low read voltage offers significant power savings. Conventional memory (e.g., CMOS based-memory) always requires high power (voltage) reading and thus consumes orders of magnitude more power. In addition, many conventional memory technologies require constant refreshing of stored data which also consumes high amounts of power. Low power consumption also aids in reduction of thermal energy.

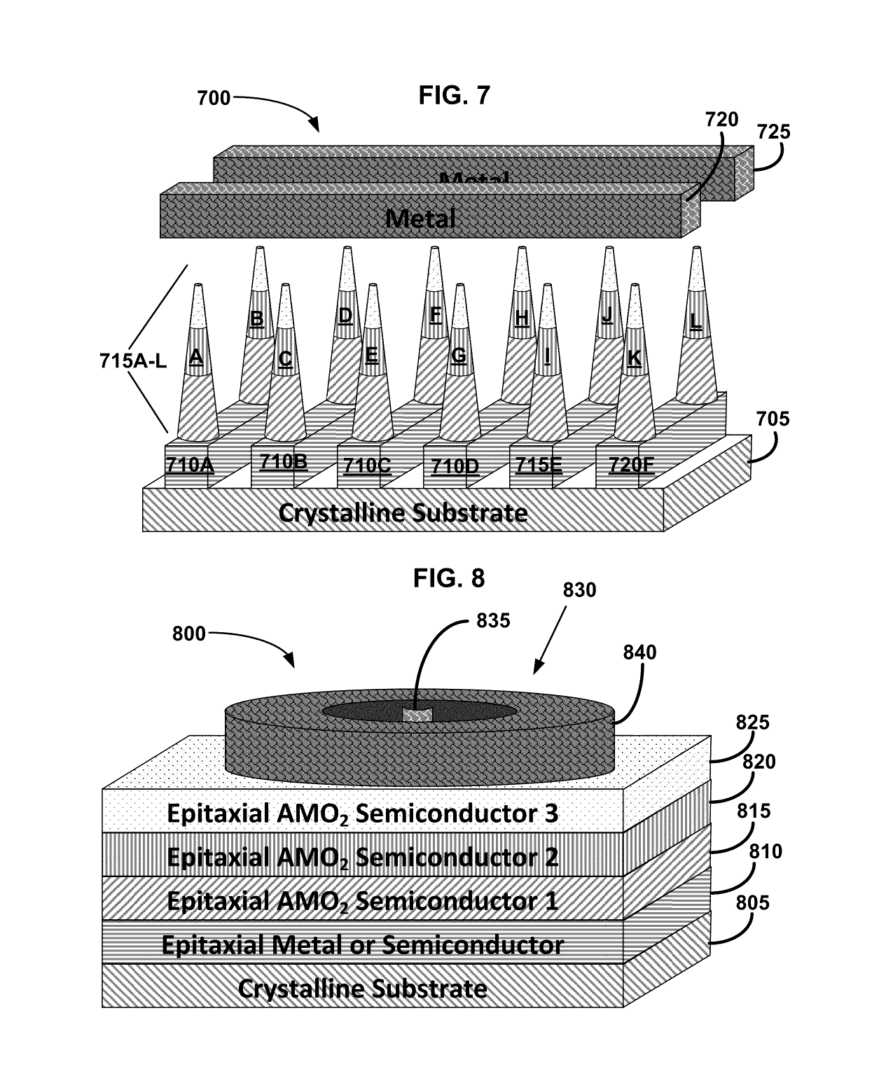

FIG. 7 illustrates a partially exploded view of another memristor device 700 in accordance with some embodiments of the present invention. As shown the device generally includes a substrate 705, a plurality of rectangular-shaped cross bars 710A-F, a plurality of conical columns 715A-L, and dual top electrodes 720, 725. The device 700 can be made by etching the stack 500 so that the components illustrated in FIG. 6 are sized and shaped as illustrated. In currently preferred embodiments, the layers making of the cells 715A-L can include multiple epitaxial semiconductor layers like those discussed regarding FIG. 5 (i.e., layers 515, 520, 525). The dual top electrodes 720, 725 are shown exploded upwards for clarity (only two electrodes of many shown). In actual use, the dual top electrodes 720, 725 would be coupled to the conical columns 715A-L (in a manner similar to that shown in FIG. 6).

The device 700 is a vertical constrictive current flow device and illustrates one possible implementation of constrictive current flow geometry. Constrictive current flow geometry aids in amplified resistance changes due to dopant density variations with one dimensional ion flow. Since resistance is determined in large part by doping density and ion (doping) density is varied along the direction of electric field, changing device dimensions in directions normal to the applied electric field, the doping density and thus resistivity can be varied non-linearly (since area goes as device dimension squared). For example, and with reference to FIG. 7, if an electric field drives ions toward a small size end of the columns 715A-L constraining the ion current flow, ion density in this region rises non-linearly making the doping density in this region of the device rapidly increase. Conversely, ions flowing into the small geometry region came from the large geometry region. Since the ion (doping) density in this larger region changes more slowly, the resistance of this region changes less.

The shape of the conical columns 715A-L enables the device 700 to have an exaggerated resistance change range. In this fashion, the conical columns can represent a broad range of resistance values and memory values. Relative to non-tapered structures, constrictive current flow geometry (like conical columns 715A-L) concentrates the electric fields that drive ions in smaller (along the linear length) device regions amplifying the ion motion effect making the device respond faster to applied electric field. The geometry of the columns 715A-L are just one configuration for pillars forming memristor cells in accordance with embodiments of the present invention. Any geometry that constrains ion flow under applied electric fields can accomplish this same effect.

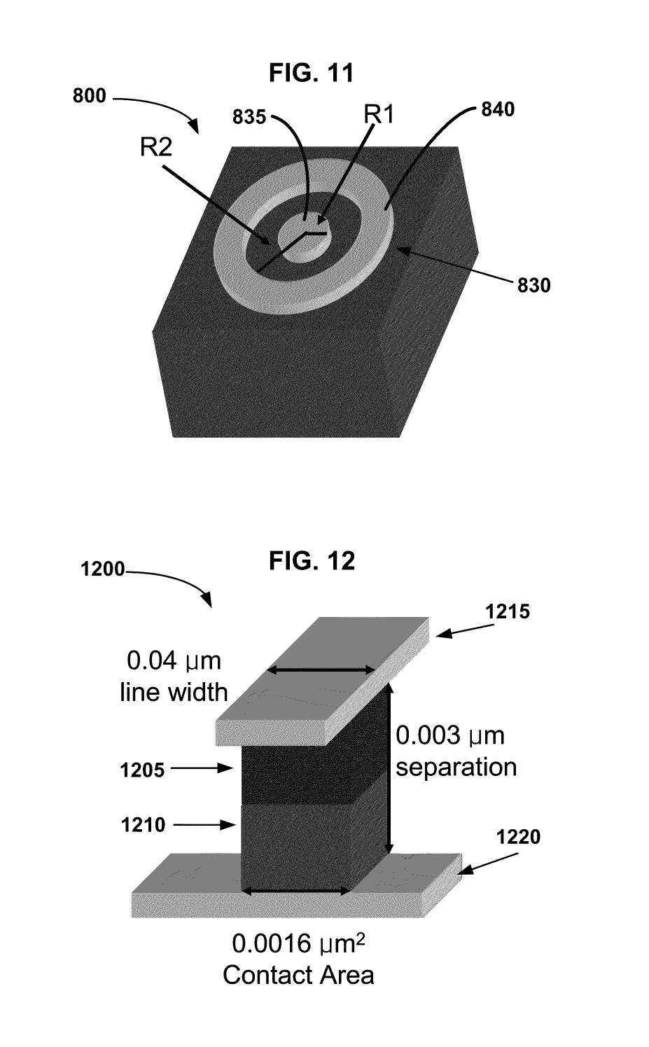

FIG. 8 graphically illustrates another memristor device 800 in accordance with some embodiments of the present invention. As shown, the device 800 generally includes a substrate 805, several epitaxial layers 810, 815, 820, 825, and a top radial electrode 830. The radial electrode 830 can include an inner electrode 835 and an outer electrode 840. FIG. 11 shows an angled top perspective of the radial electrode 830. The device 800 is a vertical constrictive current (both ion and electronic) flow device and illustrates one implementation of a lateral constrictive current flow geometry. With reference to FIG. 11, the R1 and R2 radial lengths can be varied to vary the degree of constrictive current flow geometry. As mentioned above, constrictive current flow geometry results in amplified resistance changes due to dopant density variations with one dimensional ion flow.

The lateral constrictive flow device does not require the use of semiconducting or epitaxial metals as a bottom contact and thus can be grown on insulating materials or materials useful for high speed operation. In the device 800, electric fields and thus ion/dopant flow is radially directed due to the radial electrode 830. Application of an electric field drives dopants toward or away from the smaller center contact 835 of the top radial electrode 830. This constriction/expansion of the doping provides a non-linear change in resistance with applied field greatly amplifying the resistance change and the speed for resistances to be changed.

FIG. 12 schematically illustrates a memristor cell 1200 in concert with a cross-bar access arrangement in accordance with some embodiments of the present invention. The memristor cell 1200 can be fabricated as discussed herein and can be made with one or more layers of metal oxide semiconductors. As pictured, the memristor cell 1200 includes two layers 1205, 1210 of semiconductor material (sometimes call memory layers). The memristor cell 1200 is also pictured with access lines 1215, 1220 (in some embodiments, the access lines 1215, 1220 may be said to form part of the memristor cell 1200). The access lines 1215, 1220 can also be thought of as electrodes or as contacts to provide an electrical potential across the memory layers 1205 for reading and writing of data.

As discussed above, access lines (such as access lines 1215, 1220) can be used to program the memristor cell 1200 to have a resistance and also to determine a resistance that has been previously programmed in the memristor cell 1200. By programming a resistance, a data value or data state can be stored in the memristor cell. And by determining a programmed resistance, a data value or data state can be retrieved from the memristor cell 1200. While the memristor cell is shown in a cross-bar type of arrangement with memory layers 1205, 1210 positioned intermediate spaced apart perpendicular access lines 1215, 1220, other embodiments may include different access and memory layer configurations. For example, access lines can include access lines (or electrodes) of varying shape and design (e.g., radial electrodes, patterned semiconductors, metal electrodes, semiconductors). Memory layer configurations can include various geometric shapes.

Another feature illustrated in the memristor cell 1200 is large contact spacing. Due to the physical properties of materials discussed herein, the memristor cell 1200 can have contact spacing greater than about 10 microns. Existing memristor technology is all nanoscale-type devices and such size may not be desired for all applications. Thus, embodiments of the present invention include the ability to provide both micron-scale and nano-scale devices.

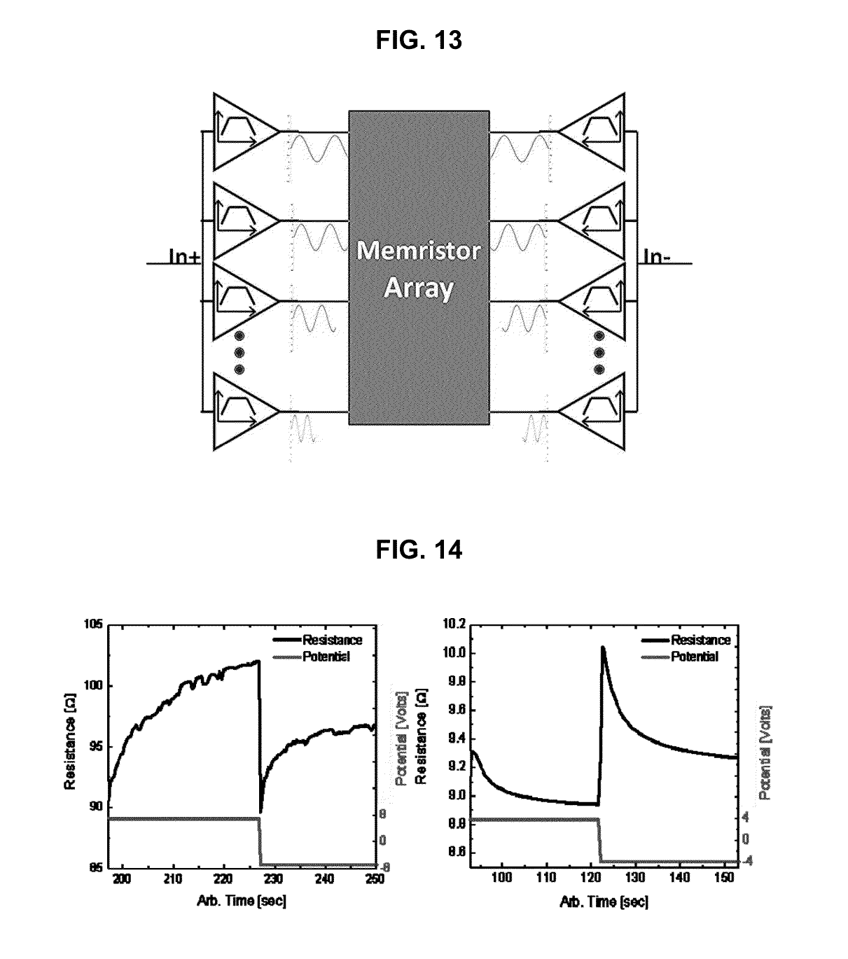

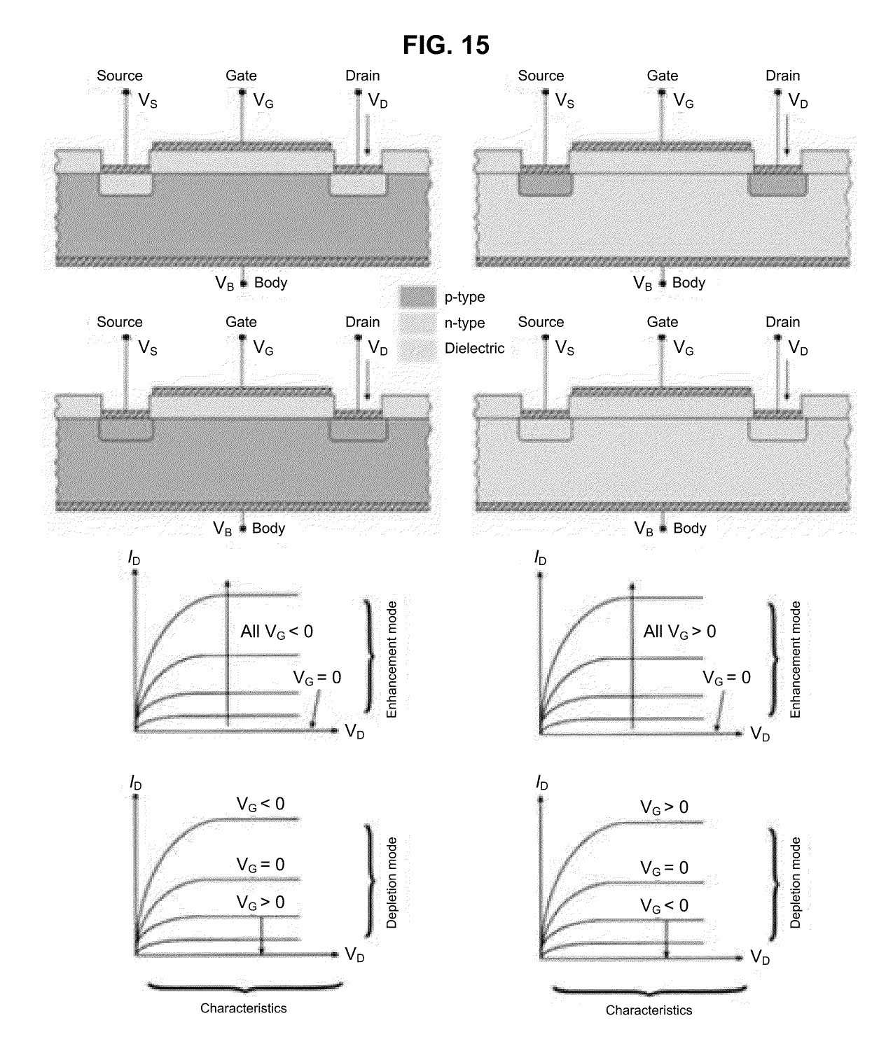

Those of skill in the art will understand that the memristor cell 1200 can be included with a plurality of other cells to form a memristor array. FIG. 13 shows a sample memristor array with various inputs and outputs. FIG. 13's array can include and be formed with a plurality of any of the various memristance devices discussed, including those illustrated in FIGS. 5-12. The array can include both 2D and 3D arrangements of sub-memristor arrays.

### Complementary Memristance Features (Both N-Type and P-Type)

Another feature of the present invention includes providing complementary-type memristance devices. FIG. 13 graphically depicts how a complementary (both n-type (left) and p-type (right)) memristor's resistance can change (increasing or decreasing) in time as an electric field is applied. In accordance with some embodiments of the invention, memristors (e.g., LiNbO₂ memristors) can be grown natively n-type or p-type. This is believed to be an unusual quality for an oxide semiconductor. N-type material can be grown with near stoichiometric Li content and is deficit in oxygen. P-type is grown with near stoichimetric or only slightly deficient oxygen content and instead as-grown or electrically doped to have a deficiency of Li. Since Li vacancies act as acceptors, the motion of Li in response to an electric field can moves dopants. This can create areas of high and low doping within one or more semiconductor material layers. This in turn changes the resistance of the device. As shown in FIG. 13, the resistance change can be either increasing or decreasing in time in response to an applied electric field. This dual increasing and decreasing in resistance over time can implement a complementary memristor technology. This is believed to be the very first this has been accomplished because traditional n-type memristors can only have decreasing polarity with time.

The flexibility as well as the superb electrical and structural quality of the complementary memristor affords another advantage not available in other ionic/electronic materials—the potential for complementary or bipolar (both n and p-type) devices. LiNbO₂ affords the opportunity to have all four types of MISFET operations, n/p-channel, enhancement/depletion. This flexibility affords the possibility of having not just complementary (n/p type) memristors, but also memdiodes and memtransitors. Indeed, field reconfigurable electronics can be created via application of electric field. In principle, a p-channel enhancement transistor can be converted to a n-channel depletion for example. A memristor can also be converted to a diode or transistor by appropriate application of an electric field. This feature solves signal fan-out and bi-directionality in neuromorphic circuits, but also allows unprecedented generalized reconfigurability. Consider an amplifier designed for bipolar power supplies where one supply fails in the battle field. Reconfigure the amp for unipolar operation and operation can continue.

Further, and as shown in FIG. 14, when voltage polarity is reversed, a near instantaneous recovery of the original resistance is observed although device dimension is 1000's of times larger than any other reported memristor. Traditional n-type memristors can only have decreasing resistance (excitatory synapse behavior) with time and no other memristor material has ever demonstrated memristance at macroscopic (10's-100's of um) length scales.

### Memristor Based Transistors—Memtransistors

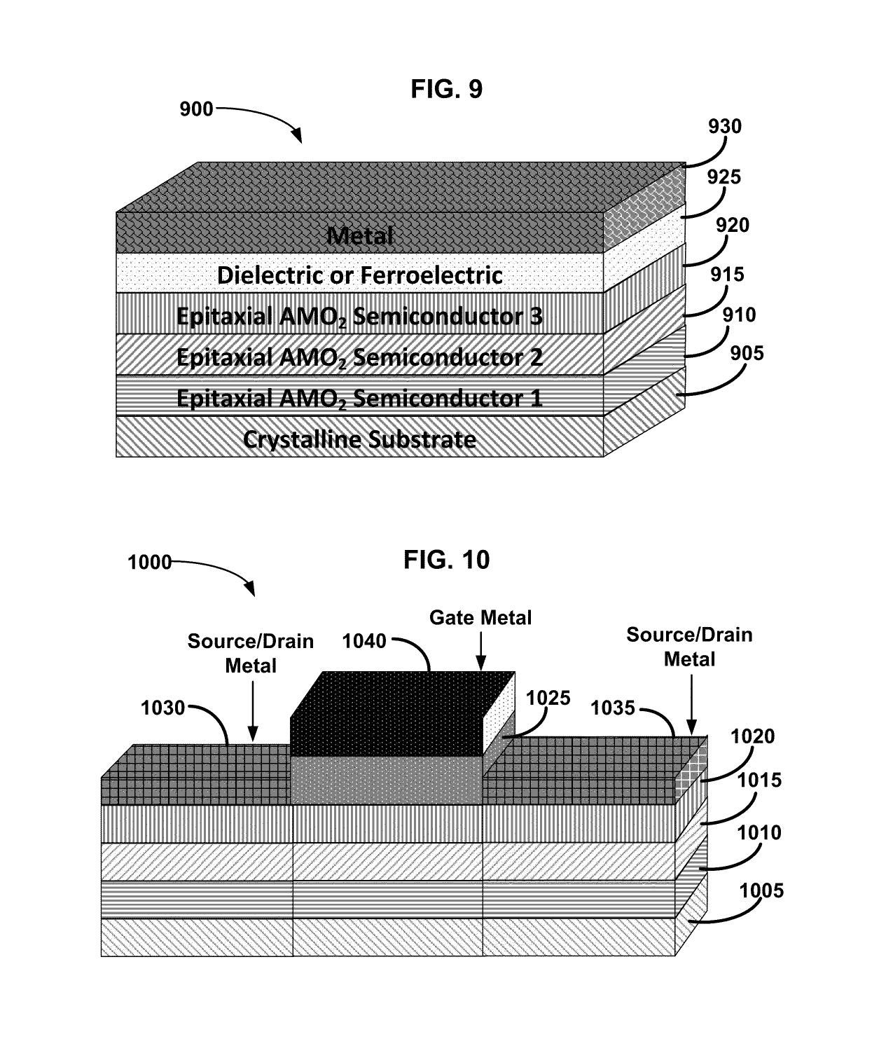

FIG. 9 graphically illustrates a multi-layer epitaxial stack 900 that can be used in a process to fabricate a memtransistor device in accordance with some embodiments of the present invention. The stack 900 is in some respects similar to the stack 500. For example, the stack 900 includes a substrate 905, epitaxial semiconductor layers 910, 915, 920, a dielectric or ferroelectric layer 925, and a metal layer 930. By utilizing the dielectric or ferroelectric layer 925 as an electronic (electron/hole) insulating layer (e.g., a dielectric, wide bandgap ferroelectric such as LiNbO₃ or LiTaO₃) and by making electrical contact to two adjacent AMO₂ semiconductor regions, a transistor or memtransistor structure can be implemented.

A currently preferred transistor embodiment includes an insulator layer 925 that is a Li saturated dielectric such as LiNbO₃ or LiTaO₃ so that both ionic (Li ions) and electronic (electrons/holes) insulation is achieved. While no limitation on the dielectric layer 925 is implied, ferroelectric switching can be implemented by use of ferroelectric layers LiNbO₃ and/or LiTaO₃ or alloys. Having a ferroelectric insulator as layer 925 allows for “static memory” that retains its state indefinitely. LiNbO₃ or LiTaO₃ are very closely lattice matched to the AMO₂ family of semiconductors.

The semiconductor layers 910, 915, 920 could be as simple as one AMO₂ layer (all three layers identical) or any combination of AMO₂ heterostructures. For example, an ion source/sink buried layer 910 could be used to electrically program the upper layers 915, 920 to convert layers 915, 920 from n-type to p-type and vice versa. Layer 920 and/or alternatively both layers 910, 920 can be selected as a higher bandgap semiconductor. This can enable a high mobility (high speed) heterojunction transistor commonly known as a HEMT (high electron mobility transistor) within the AMO₂ material system. Memtransistor structures according to the present invention can range from simple to complex heterojunctions with ion sources and ion sinks. Application of various applied source/gate/drain voltage can be used to adjust the conductivity of the channel or source/drain region (magnitude of doping changed and/or flipping the polarity type n/p) while the gate voltage can be used to further modulate the channel conductance.

FIG. 10 graphically illustrates a memtransistor device 1000 in accordance with some embodiments of the present invention. The memtransistor device 1000 includes several layers that are similar to FIG. 9, including a substrate 1005, epitaxial semiconductor layers 1010, 1015, 1020, and a dielectric or ferroelectric layer 1025. The dielectric or ferroelectric layer 1025 can be etched to be positioned in a central area of the device 1000. Metal portions 1030, 1035, 1040 can be placed on either side of layer 1025 and on top of the layer 1025. In this fashion, the metal portions 1030, 1035, 1040 can be utilized to act as transistor source, gate, and drain electrodes.

The memtransistor device 1000 is a generic device that can be used to implement numerous devices in response to programming charges applied to the metal portions 1030, 1035, 1040. The various potential programmable devices include, but are not limited to: (1) a one transistor memristance programmed memory element; (2) a transistor whose gain can be adjusted via memristance effects; (3) a heterojunction transistor in the AMO₂ semiconductor family; and (4) a single transistor that can be reconfigured through application of appropriate source/drain/gate voltages to produce any combination of NMOS depletion mode, NMOS enhancement mode, PMOS depletion mode and PMOS enhancement mode electronic behavior. In accordance with the present invention programming charges can alter how the memtransistor device 1000 functions.

For example, application of an applied voltage to source/drain regions 1030, 1035, 1040 can change the conductivity of the source/drain and even convert a p-type region to n-type (or vice versa) making an entirely different current-voltage characteristic. Likewise, application of a DC gate voltage can modulate the ion/dopant density of the channel region of the device 1000 changing turn on voltages, pinch off voltages and channel resistance. Sufficiently large gate voltages or owing to the analog nature of the memristive sub-elements comprising the memtransistor, long exposure to small DC voltages can even switch the polarity of the channel from n-type to p-type and vice versa—again resulting in entirely different current voltage characteristics. The combination of these features enables the new memtransistor device 1000 to switch current-voltage characteristics from any combination of those commonly found in NMOS enhancement, NMOS depletion, PMOS enhancement, and PMOS depletion mode transistors. Any of these ion programmable features can be held static by using AC source, drain and gate voltages for readout and processing whereas DC voltages will program the device into the desired mode of operation.

### Photovoltaic/Solar Cell Applications & Devices

Embodiments of the present invention also include photovoltaic or solar cell applications. The semiconductor materials discussed in this application can be used to fabricate solar cells for use in capturing and harnessing solar energy. An exemplary embodiment includes a transformative integrated photovoltaic/battery that is capable of storing its own energy in an internal battery without the need for additional materials or construction. This integrated solar cell-battery also can be configured to produce hydrogen from photo-electrolytic water splitting (discussed below in more detail).

Existing solar cells generally require a large area to collect power because the solar flux is limited to about 100 mW/cm². Since any implementation of a solar cell requires a significant surface area to produce power, the present invention combines this area with a battery area for charge storage. Batteries are multiple layers of materials rolled or stacked in a space saving form. Embodiments of the present invention include an Integrated Photovoltaic Battery (IPB). The integrated nature of an IPB eliminates the redundancy in area/weight enabling a single device to produce power while also being charged by exposure to the sun.

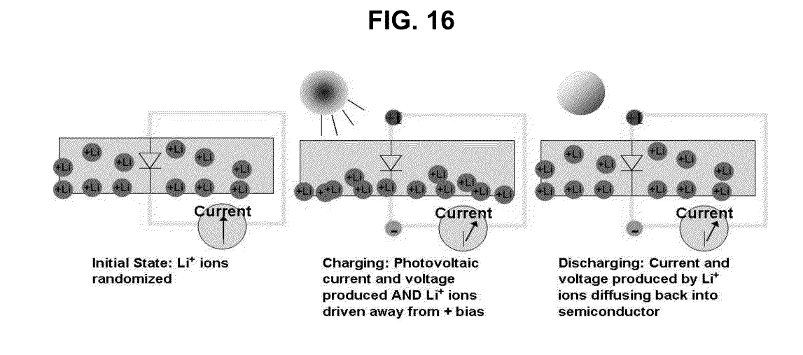

FIG. 16 schematically illustrates an exemplary solar cell semiconductor device (e.g., an IPB) in accordance with some embodiments of the present invention. The illustration shows that an IPB can have an initial mode, a solar cell/charging mode, and a battery/discharging mode. The IPB can include a solar cell integrated with a Lithium-based semiconductor as discussed in this application (e.g., layers 515, 520, 525). Integration enables a solar cell to generate power (charging mode) for storage in the integrated Lithium-based semiconductor. This can occur when voltage generated by the solar cell would also bias the Lithium-based semiconductor device so that Li⁺ ions are driven toward the bottom of the device.

When solar is removed (discharging mode), the balancing voltage that drove the Li toward the cathode is also removed resulting in Li diffusion back into the semiconductor and consequentially current flow with the same polarity as the photovoltaic current. In principle, many Li diffused semiconductors can accomplish the task described. In practice, however, solubility limits of Li in most semiconductors along with large changes in volume when Li is removed/inserted results in impracticality (even fracturing) for most materials. Semiconductors discussed in this application are ideal for IPBs because they naturally include Li and do not change volume significantly when Li is added or removed. In addition, semiconductors discussed in this application are high quality, crystalline materials that can absorb light efficienctly and have long minority carrier lifetime to support photovoltaic action and carrier separation.

### Water Splitting & Hydrogen Generation Applications & Devices

Embodiments of the present invention also include water splitting or hydrogen generation applications. The materials described herein can solve many of the problems impeding currently existing photo-electrolytic water splitting concepts/designs to produce hydrogen.

Generally, photo-electrolytic water splitting is accomplished with a semiconductor of appropriate energy characteristics. That is, the energy gap of the semiconductor must be greater than the H₂O redox potentials (i.e., greater than about 1.8 eV), yet the energy gap must be sufficiently small to allow the semiconductor to absorb light (i.e., less than about 2.2 eV). Light is absorbed by the semiconductor materials, and it generates electron-hole pairs that can diffuse to the semiconductor surface, which requires the long minority carrier lifetimes or high electrical qualities of the oxide compositions described above. At the semiconductor electrolyte interface, electrons are injected into a water solution creating excess H₂ while holes are injected at the opposing (or same) electrode facilitating O₂ production.

The oxide materials described above, and particularly the Li-based oxide materials, are photo-chemically stable in aqueous solutions. In addition, the Li-based oxide materials described above have energy band gaps of about 2 to about 2.5 eV, allowing for efficient solar spectrum absorption. Most existing oxide materials that have been candidates for such applications either suffer from poor photo-chemical stability or too large of a band gap. In contrast, the oxide materials described herein can exhibit both desirable properties. In some cases, the pH of the water can be used to adjust the redox potentials of the water so as to provide improved alignment to the energy bands of the oxide material.

In another beneficial feature for photo-electrolytic water splitting, the oxides materials described herein have the ability to exhibit excellent p-type conductivity, which makes them less sensitive to interfacial charge transfer effects. That is, since the hole densities of these materials can be in excess of 1×10²¹ cm⁻³, they appear almost metallic in character. As a result, the semiconductor oxide materials will not undergo interfacial charge distribution distortions that drive charge carriers away from the semiconductor-electrolyte interface.

The above described features of the oxide materials disclosed herein can meet the requirements for materials needed for photo-electrolytic water splitting so as to be implemented in such processes. In an exemplary embodiment, a single crystal epitaxial film of a p-type oxide material, such as Li-deficient LiNbO₂, can be disposed on a substrate, and the combined device (i.e., the film and substrate) can be contacted with water. When a photon impinges a surface of the oxide film, an electron/hole pair is generated. The electron and hole migrate to the surface of the substrate and can be injected separately into water (provided they do not recombine beforehand). The electron can be used to produce H₂, while the hole can be used to produce O₂. If the hydrogen gas and the oxygen gas do not recombine to form water, they can be subsequently processed using known hydrogen/oxygen separation techniques.

In some cases, a p-n junction can be used to promote better separation of the electron and hole generated by absorption of the photon. In this manner, the opportunity to recombine can be decreased.

### CONCLUSION

The embodiments of the present invention are not limited to the particular formulations, process steps, and materials disclosed herein as such formulations, process steps, and materials may vary somewhat. The terminology employed herein is used for the purpose of describing exemplary embodiments only and the terminology is not intended to be limiting since the scope of the various embodiments of the present invention will be limited only by the appended claims and equivalents thereof. Indeed, the above descriptions are exemplary and yet other features and embodiments exist.

Therefore, while embodiments of the invention are described with reference to exemplary embodiments, those skilled in the art will understand that variations and modifications can be effected within the scope of the invention as defined in the appended claims. Accordingly, the scope of the various embodiments of the present invention should not be limited to the above discussed embodiments. Rather, the full scope of the invention and all equivalents should only be defined by the following claims and all equivalents.

I claim:

1. A semiconductor device, comprising:
a first layer of a first variable resistance material defining a first surface, the first variable resistance material being programmable to be one of an n-type or a p-type material;
a second layer of a second variable resistance material defining a second surface, the second variable resistance material being programmable to be one of an n-type or a p-type material;
the first layer being disposed proximate the second layer with the first surface and the second surface and defining a boundary interface between the first and second layers; and
an electrical charge source in electrical communication with the first and second layers to supply a charge for programming resistances for the first variable resistance material and the second variable resistance material.

2. The semiconductor device of claim 1, wherein the first layer and the second layer are formed with metal oxide semiconductor materials comprising:
a substrate; and
a single-crystal epitaxial layer of an oxide composition disposed on a surface of the substrate;
wherein the oxide composition is represented by ABO₂ such that A is a lithium cation, B is a cation selected from the group consisting of trivalent transition metal cations, trivalent lanthanide cations, trivalent actinide cations, trivalent p-block cations, and combinations thereof, and O is an oxygen anion;
wherein a unit cell of a crystal structure of the oxide composition comprises a first layer comprising a plane of lithium cations and a second layer comprising a plurality of edge-sharing octahedra having a B cation positioned in a center of each octahedron and an oxygen anion at each corner of each octahedron; and
wherein the first layer and the second layer of the unit cell are alternatingly stacked along one axis of the unit cell.

3. The semiconductor device of claim 1, wherein the first layer and the second layer are formed with Lithium Niobite (LiNbO₂).

4. The semiconductor device of claim 1, further comprising a first electrode in electrical communication with the first layer and a second electrode in electrical communication with the second layer, the first and second electrodes being the electrical charge source.

5. The semiconductor device of claim 1, further comprising a third layer of a third variable resistance material defining a third surface, the third variable resistance material being programmable to be one of an n-type or a p-type material, the third layer being positioned proximate the second layer to form a second interface boundary and also being in electrical communication with the charge source.

6. The semiconductor device of claim 1, wherein the first and second layers are formed in at least one of a polygonal or circular shape.

7. The semiconductor device of claim 1, wherein the first and second layers are part of at least one of a memory cell, memristor, memdiode, memtransistor, or charge storage device.

8. The semiconductor device of claim 1, wherein the first and second layers are doped at varying density levels.

9. The semiconductor device of claim 1, wherein the electrical charge source is a radial electrode disposed to apply an electric charge between an inner electrode and an outer electrode, the radial electrode being positioned on the first layer.

10. The semiconductor device of claim 1, wherein the first and second layers comprise ions/dopants that flux in response to the charge from the electric charge source.

11. A semiconductor device, comprising:
a first electrode and a second electrode;
a metal-oxide-semiconductor region disposed in electrical communication with the first electrode and the second electrode;
the metal-oxide-semiconductor region comprising a first epitaxial metal layer doped at a first doped level, a second epitaxial metal layer doped at a second doped level, and a third epitaxial metal layer doped at a third doped level;
the first epitaxial layer, the second epitaxial layer, and the third epitaxial layer being positioned proximate to each other to form a first boundary interface between the first epitaxial layer and the second epitaxial layer and a second boundary interface between the second epitaxial layer and the third epitaxial layer; and
the first epitaxial layer, the second epitaxial layer, and the third epitaxial layer comprising a material enabling ion movement across the first and second boundary interfaces to enable varying resistance of the metal-oxide-semiconductor region.

12. The semiconductor device of claim 11, the first and the third epitaxial metal layers being formed of a first material and the second epitaxial metal layer being formed of a different material so that the metal-oxide semiconductor region is a symmetric heterostructure.

13. The semiconductor device of claim 11, wherein the first and second electrodes are configured to apply an electric potential across the metal-oxide-semiconductor region to enable ion/dopant flux across the first and second boundary interfaces.

14. The semiconductor device of claim 11, wherein the first epitaxial layer, the second epitaxial layer, and the third epitaxial layer are sized and shaped to have at least one of a polygonal or circular cross-section.

15. The semiconductor device of claim 11, wherein the first epitaxial layer, the second epitaxial layer, and the third epitaxial layer are sized and shaped in a vertical column that is tapered toward the first electrode.

16. The semiconductor device of claim 11, wherein the first epitaxial layer, the second epitaxial layer, and the third epitaxial layer are sized and shaped with a geometry configured to constrict ion and electric current flow.

17. The semiconductor device of claim 11, wherein the first epitaxial layer consists only of LiNbO₂, the second epitaxial layer consists only of LiCoO₂, and the third epitaxial layer consists only of LiNbO₂.

18. The semiconductor device of claim 11, wherein the first epitaxial layer consists only of LiCoO₂, the second epitaxial layer consists only of LiNbO₂, and the third epitaxial layer consists only of LiCoO₂.

19. The semiconductor device of claim 11, wherein the first doped level and the third doped level have a positive charge and the second doped level has a negative charge.

20. The semiconductor device of claim 11, wherein the first doped level and the third doped level have a negative charge and the second doped level has a positive charge.

21. The semiconductor device of claim 11, wherein the first epitaxial layer, the second epitaxial layer, and the third epitaxial layer are doped at varying density levels.

22. The semiconductor device of claim 11, wherein the metal-oxide semiconductor region is part of at least one of a memory cell, memristor, memdiode, memtransistor, or charge storage device.

23. The semiconductor device of claim 11, further comprising a dielectric/ferroelectric material situated on a portion of the metal-oxide-semiconductor region and intermediate the first and second electrodes, and further comprising a third electrode situated in electrical communication with the dielectric/ferroelectric material.

24. A semiconductor device, comprising:
a crystalline substrate and a plurality of electrodes spaced apart from the crystalline substrate;
an array of variable resistance pillars being disposed between the crystalline substrate and at least one of the electrodes; and
the array of variable resistance pillars each comprising at least two layers of epitaxial-metal-oxide semiconductor materials, the semiconductor materials comprising metal oxide compositions enabling ion/dopant flux through the variable resistance pillars in response to an electric potential, and wherein said variable resistance pillars can retain a resistance value as a function of charge associated with the electric potential.

25. The semiconductor device of claim 24, wherein each of the variable resistance pillars forms part of a memory cell, memristor, memdiode, memtransistor, or charge storage device.

26. The semiconductor device of claim 24, wherein the array of variable resistance pillars comprises up to three layers of epitaxial-metal-oxide semiconductor materials, and each of the pillars are one of symmetric heterostructures and symmetric heterostructures.

27. The semiconductor device of claim 24, wherein the array of variable resistance pillars comprises up to three layers of epitaxial-metal-oxide semiconductor materials, and each of the three layers is a Lithium based metal oxide semiconductor.

28. The semiconductor device of claim 24, further comprising a network of read/write access lines configured to be in communication with each of the array of variable resistance pillars to enable detection and programming of a resistance value for each of the array of variable resistance pillars.

29. The semiconductor device of claim 24, wherein the array of variable resistance pillars can write and erase a resistance value without application of a set/reset voltage.

30. The semiconductor device of claim 24, wherein the array of variable resistance pillars has a length ranging from about 10 microns to 100 microns.

31. The semiconductor device of claim 24, wherein one of the electrodes is positioned proximate the substrate and between at least one of the pillars and the other electrode is positioned proximate an opposing end of the pillars and wherein the distance between said electrodes is greater than about 10 microns.

32. The semiconductor device of claim 24, wherein the array of variable resistance pillars have a ratio of programmable resistance values equal to or exceeding about 1000:1 from a maximum resistance value to a minimum resistance value.

33. The semiconductor device of claim 24, wherein each of the variable resistance pillars forms part of a memory cell, with each memory cell having an infinite number of data states.

34. The semiconductor device of claim 24, wherein each of the variable resistance pillars forms part of a memory cell, with each memory cell having more than two data states.

35. A semiconductor device, comprising:
a first layer of a first variable resistance material defining a first surface and a second surface opposed from the first surface, the first variable resistance material being programmable to be one of an n-type or a p-type material;
the first layer comprising material to transport holes and electrons between the first surface and the second surface in response to electric potential; and
an electrical charge source in electrical communication with the first layer to supply the electric potential for programming resistances for the first variable resistance material.

36. The semiconductor device of claim 35, further comprising:
a second layer of a second variable resistance material, the second variable resistance material being programmable to be one of an n-type or a p-type material;
a third layer of a third variable resistance material, the third variable resistance material being programmable to be one of an n-type or a p-type material;
the second and third layers stacked on the first layer and in electrical communication to receive electric potential from the electrical charge source and in response transporting holes and electrons for programming resistances for the second and third variable resistance materials.

37. The semiconductor device of claim 36, wherein the first layer, second layer, and third layer are configured to be programmable to be programmed to an N-type transistor or a P-type transistor in response to charges provided by the electrical charge source, wherein a DC voltage is applied the electrical charge sources for programming.

38. The semiconductor device of claim 37, wherein the first layer, second layer, and third layer are held in the programmed state by using an AC source for data readout and processing operations.

39. The semiconductor device of claim 35, wherein the first layer comprises a plurality of sub-layers and wherein boundaries between the sub-layers form boundary interfaces, and wherein in response to electric potential the sub-layers source or sink ions/dopants to vary the resistance of the first layer.

40. The semiconductor device of claim 35, wherein the electrical charge source is a solar cell configured to convert light into an electric potential for delivery to the first layer.

41. The semiconductor device of claim 35, further comprising a second layer of semiconductor material that is programmed to be a memtransistor, and wherein the first layer is formed to be a memtransistor, and wherein the memtransistor are arranged in a complementary fashion to form a complementary memtransistor.
